(19) United States
(12) Patent Application Publication
(10) Pub. No.: US 2022/0375411 A1
(43) Pub. Date: Nov. 24, 2022

(54) SHIFT REGISTER AND DRIVING METHOD THEREOF, AND DISPLAY PANEL

(71) Applicant: Xiamen Tianma Micro-Electronics Co.,Ltd., Xiamen (CN)

(72) Inventors: Mengmeng ZHANG, Shanghai (CN); Xingyao ZHOU, Shanghai (CN)

(21) Appl. No.: 17/381,668

(22) Filed: Jul. 21, 2021

(30) Foreign Application Priority Data
May 19, 2021 (CN) 202110548291.8

(51) Int. Cl. G09G 3/3266; G09G 3/3225; G11C 19/28

(52) U.S. Cl. CPC G09G 3/3266; G09G 3/3225; G11C 19/28; G09G 2310/0286; G09G 2310/08

(57) ABSTRACT

A shift register and its driving method, and a display panel are provided in the present disclosure. The shift register includes a first pull-down module, configured to, in response to a conduction level of a first node, transmit a first clock signal of a first clock signal output terminal to a first output terminal; further includes a first pull-up module, configured to, in response to a conduction level of a second node, transmit a first cut-off level signal of a first cut-off level voltage terminal to the first output terminal; and further includes a first node control module, configured to, when the first cut-off level signal is outputted at the first output terminal, transmit a second cut-off level voltage signal outputted from one of an input terminal and a second cut-off level voltage terminal to the first node.

### CROSS-REFERENCE TO RELATED APPLICATION

This application claims the priority of Chinese Patent Application No. 202110548291.8, filed on May 19, 2021, the content of which is incorporated herein by reference in its entirety.

### TECHNICAL FIELD

The present disclosure generally relates to the field of display technology and, more particularly, relates to a shift register and its driving method, and a display panel.

### BACKGROUND

In the field of display technology, the pixel array of an organic light-emitting diode (OLED) display panel may include multiple rows of gate lines and multiple columns of data lines. For driving gate lines, for example, a gate electrode driving circuit including multiple cascaded shift registers may be used to provide switching state voltage signals for the multiple rows of gate lines, thereby controlling the multiple rows of gate lines to be turned on sequentially.

However, when the shift register outputs a cut-off level voltage signal (e.g., a high-level voltage signal), the unstable output problem may occur.

### SUMMARY

One aspect of the present disclosure provides a shift register. The shift register includes a first pull-down module, a first pull-up module and a first node control module. A control terminal of the first pull-down module is electrically connected to a first node, a first terminal of the first pull-down module is electrically connected to a first clock signal output terminal, and a second terminal of the first pull-down module is electrically connected to a first output terminal of the shift register, which are configured to, in response to a conduction level of the first node, transmit a first clock signal of the first clock signal output terminal to the first output terminal. A control terminal of the first pull-up module is electrically connected to a second node, a first terminal of the first pull-up module is electrically connected to a first cut-off level voltage terminal, and a second terminal of the first pull-up module is electrically connected to the first output terminal, which are configured to, in response to a conduction level of the second node, transmit a first cut-off level signal of the first cut-off level voltage terminal to the first output terminal. The first node control module is electrically connected to each of the first node, an input terminal of the shift register and a second cut-off level voltage terminal, which is configured to, when the first cut-off level signal is outputted at the first output terminal, transmit a second cut-off level voltage signal outputted from one of the input terminal and the second cut-off level voltage terminal to the first node; and a voltage value of the second cut-off level voltage signal is greater than a voltage value of the first cut-off level signal.

Another aspect of the present disclosure provides a driving method of a shift register. The shift register includes a first pull-down module, a first pull-up module and a first node control module. A control terminal of the first pull-down module is electrically connected to a first node, which is configured to, in response to a conduction level of the first node, transmit a first clock signal of a first clock signal output terminal to a first output terminal. A control terminal of the first pull-up module is electrically connected to a second node, a first terminal of the first pull-up module is electrically connected to a first cut-off level voltage terminal, and a second terminal of the first pull-up module is electrically connected to the first output terminal of the shift register. The first node control module is electrically connected to each of the first node, an input terminal of the shift register and a second cut-off level voltage terminal. The driving method includes, in a cut-off level outputting stage, the first pull-up module, in response to a conduction level of the second node, transmitting a first cut-off level signal of the first cut-off level voltage terminal to the first output terminal; and the first node control module transmitting a second cut-off level voltage signal outputted from one of the input terminal and the second cut-off level voltage terminal to the first node, where a voltage value of the second cut-off level voltage signal is greater than a voltage value of the first cut-off level signal.

Another aspect of the present disclosure provides a display panel. The display panel includes a pixel array, where the pixel array includes N gate lines sequentially arranged along a first direction, and N is an integer greater than or equal to 2; and further includes a gate electrode driving circuit, where the gate electrode driving circuit includes N shift registers; along the first direction, first output terminals of N shift registers are connected to the N gate lines in a one-to-one correspondence; and a second output terminal of an n-th shift register in the N shift registers is connected to an input terminal of an (n+1)-th shift register, where n∈[1, N]. The shift register of the N shift registers includes a first pull-down module, where a control terminal of the first pull-down module is electrically connected to a first node, a first terminal of the first pull-down module is electrically connected to a first clock signal output terminal, and a second terminal of the first pull-down module is electrically connected to a first output terminal of the shift register, which are configured to, in response to a conduction level of the first node, transmit a first clock signal of the first clock signal output terminal to the first output terminal; and further includes a first pull-up module, where a control terminal of the first pull-up module is electrically connected to a second node, a first terminal of the first pull-up module is electrically connected to a first cut-off level voltage terminal, and a second terminal of the first pull-up module is electrically connected to the first output terminal, which are configured to, in response to a conduction level of the second node, transmit a first cut-off level signal of the first cut-off level voltage terminal to the first output terminal; and further includes a first node control module, where the first node control module is electrically connected to each of the first node, an input terminal of the shift register and a second cut-off level voltage terminal, which is configured to, when the first cut-off level signal is outputted at the first output terminal, transmit a second cut-off level voltage signal outputted from one of the input terminal and the second cut-off level voltage terminal to the first node; and a voltage value of the second cut-off level voltage signal is greater than a voltage value of the first cut-off level signal.

Another aspect of the present disclosure provides a display device, including the above-mentioned display panel.

Other aspects of the present disclosure can be understood by those skilled in the art in light of the description, the claims, and the drawings of the present disclosure.

### BRIEF DESCRIPTION OF THE DRAWINGS

In order to more clearly explain various embodiments of the present disclosure, the drawings required for describing the embodiments or the existing technology are briefly introduced hereinafter. Other drawings may also be obtained by those skilled in the art without any creative work according to provided drawings.

FIG. 1 illustrates an exemplary circuit structure of a shift register;

FIG. 2 illustrates an exemplary voltage signal outputted by an output terminal OUT of a shift register;

FIG. 3 illustrates an exemplary circuit diagram of a shift register according to various embodiments of the present disclosure;

FIG. 4 illustrates another exemplary circuit diagram of a shift register according to various embodiments of the present disclosure;

FIG. 5 illustrates another exemplary circuit diagram of a shift register according to various embodiments of the present disclosure;

FIG. 6 illustrates another exemplary circuit diagram of a shift register according to various embodiments of the present disclosure;

FIG. 7 illustrates another exemplary circuit diagram of a shift register according to various embodiments of the present disclosure;

FIG. 8 illustrates another exemplary circuit diagram of a shift register according to various embodiments of the present disclosure;

FIG. 9 illustrates another exemplary circuit diagram of a shift register according to various embodiments of the present disclosure;

FIG. 10 illustrates another exemplary circuit diagram of a shift register according to various embodiments of the present disclosure;

FIG. 11 illustrates another exemplary circuit diagram of a shift register according to various embodiments of the present disclosure;

FIG. 12 illustrates another exemplary circuit diagram of a shift register according to various embodiments of the present disclosure;

FIG. 13 illustrates another exemplary circuit diagram of a shift register according to various embodiments of the present disclosure;

FIG. 14 illustrates another exemplary circuit diagram of a shift register according to various embodiments of the present disclosure;

FIG. 15 illustrates another exemplary circuit diagram of a shift register according to various embodiments of the present disclosure;

FIG. 16 illustrates another exemplary circuit diagram of a shift register according to various embodiments of the present disclosure;

FIG. 17 illustrates another exemplary circuit diagram of a shift register according to various embodiments of the present disclosure;

FIG. 18 illustrates another exemplary circuit diagram of a shift register according to various embodiments of the present disclosure;

FIG. 19 illustrates an exemplary timing diagram of a shift register according to various embodiments of the present disclosure;

FIG. 20 illustrates an exemplary flow chart of a driving method of a shift register according to various embodiments of the present disclosure;

FIG. 21 illustrates another exemplary flow chart of a driving method of a shift register according to various embodiments of the present disclosure;

FIG. 22 illustrates another exemplary flow chart of a driving method of a shift register according to various embodiments of the present disclosure;

FIG. 23 illustrates another exemplary flow chart of a driving method of a shift register according to various embodiments of the present disclosure;

FIG. 24 illustrates another exemplary flow chart of a driving method of a shift register according to various embodiments of the present disclosure;

FIG. 25 illustrates another exemplary flow chart of a driving method of a shift register according to various embodiments of the present disclosure;

FIG. 26 illustrates another exemplary flow chart of a driving method of a shift register according to various embodiments of the present disclosure; and

FIG. 27 illustrates a structural schematic of a display panel according to various embodiments of the present disclosure.

### DETAILED DESCRIPTION

The features and exemplary embodiments of each aspect of the present application are described in detail hereinafter. In order to clearly illustrate the objectives, technical solutions, and advantages of the present application, the present application is further described in detail with reference to the accompanying drawings and embodiments. It should be understood that various embodiments described herein are only intended to explain the present application, but not to limit the present application. For those skilled in the art, the present application may be implemented without some of these details. The following description of various embodiments is only to provide a better understanding of the present application by showing examples of the present application.

It should be noted that in the present specification, relational terms such as “first” and “second” are only used to distinguish one entity or operation from another entity or operation, and does not necessarily require or imply any such actual relationship or sequence between these entities or operations. Moreover, the terms “include”, “compose” or any other variations thereof are intended to cover non-exclusive inclusion, such that a process, method, article or device including a series of elements may not only include those elements, and also include other elements that are not explicitly listed, or elements inherent to the process, method, article, or equipment. If there are no more restrictions, the elements defined by the sentence “include” do not exclude the existence of other same elements in the process, method, article, or equipment that includes such elements.

It should be noted that the transistors in various embodiments are described by taking P-type transistors as an example, but are not limited to P-type transistors, and can also be replaced with N-type transistors. For P-type transistors, the conduction level is a low level and the cut-off level is a high level. When the control terminal of the P-type transistor is a low level, the first terminal and the second terminal are in conduction, and when the control terminal of the P-type transistor is a high level, the first terminal and the second terminal are turned off. In actual implementation, the gate electrode of each of the above-mentioned transistors may be used as the control terminal; moreover, according to the gate signal and type of each transistor, the first terminal may be used as a source electrode, and the second terminal may be used as a drain electrode; or the first terminal may be used as a drain electrode, and the second terminal may be used as a source electrode, which may not be distinguished herein. In addition, the conduction level and the cut-off level in various embodiments of the present disclosure may be general terms, the conduction level refers to any level which can make the transistor conducting, and the cut-off level refers to any level that can make the transistor being cut off/turned off.

In various embodiments of the present application, the term “electrically connected” may refer to the direct electrical connection of two components, or may refer to the electrical connection between two components via one or more other components.

In various embodiments of the present application, the first node, the second node, and the third node may only be defined for the convenience of describing the circuit structure. The first node, the second node, and the third node may not be actual circuit units.

Before describing the technical solutions provided by various embodiments of the present application, in order to facilitate understanding of various embodiments of the present application, the present application may first describe the problems existing in the related technologies: as mentioned above, in the existing technology, when the shift register is outputting a cut-off level voltage signal (for example, a high-level voltage signal), the unstable output problem may occur.

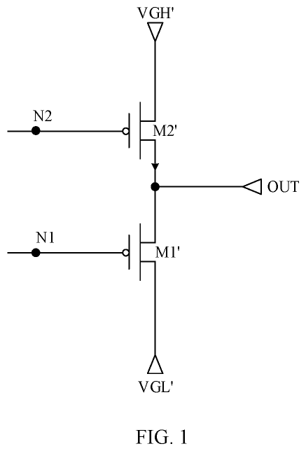

The reasons leading to the above technical problems may be described in detail below in conjunction with FIG. 1.

As shown in FIG. 1, an output terminal OUT of a shift register may output a low-level voltage signal VGL′ or a high-level voltage signal VGH′. When a first node N1 is at a conduction level and a second node N2 is at a cut-off level, a transistor M1′ may be in conduction under the control of the conduction level of the first node N1, a transistor M2′ may be cut off under the control of the cut-off level of the second node N2, and the output terminal OUT of the shift register may output the low-level voltage signal VGL′. When the first node N1 is at a cut-off level and the second node N2 is at a conduction level, the transistor M1′ may be cut off under the control of the cut-off level of the first node N1, the transistor M2′ may be in conduction under the control of the conduction level of the second node N2, and the output terminal OUT of the shift register may output the high-level voltage signal VGH′.

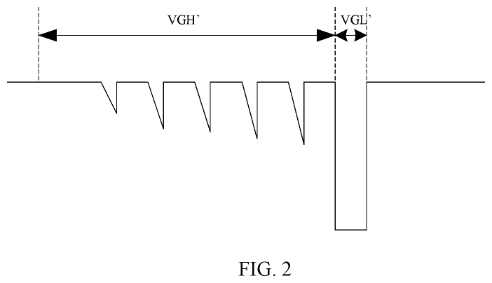

When the output terminal OUT of the shift register outputs the high-level voltage signal VGH′, the transistor M1′ may not be completely turned off due to the positive bias of the threshold voltage Vth of the transistor M1′. Therefore, the low-level voltage signal VGL′ may flow into the output terminal OUT of the shift register through the transistor M1′, and the low-level voltage signal VGL′ may further affect the high-level voltage signal VGH′ outputted from the output terminal OUT of the shift register, such that the shift register may not output a stable high-level voltage signal VGH′. FIG. 2 illustrates an exemplary voltage signal outputted by the output terminal OUT of the shift register. As shown in FIG. 2, when the output terminal OUT of the shift register outputs the high-level voltage signal VGH′, under the influence of the leakage current of the transistor M1′, the high-level voltage signal VGH′ may be pulled down various times by the leaked low-level voltage signal VGL′, and a stable output may not be maintained.

Various embodiments of the present application provide a shift register and its driving method, a gate electrode driving circuit, a display panel, and a display device to solve the unstable output problem when the shift register outputs the cut-off level voltage signal.

The technical solutions provided by various embodiments of the present application are described in the following. When a first output terminal of the shift register outputs a first cut-off level signal, a first node control module may be configured to transmit a second cut-off level voltage signal with a higher voltage value to a control terminal (first node) of a first pull-down module, thereby increasing a gate turn-off voltage of the first pull-down module and more thoroughly turning off the first pull-down module. Therefore, the influence of the conduction level signal flowing in the first pull-down module on the first cut-off level signal outputted by the shift register may be reduced, and the shift register may be ensured to output a stable first cut-off level signal.

The shift register provided by various embodiments of the present application may be first introduced hereinafter.

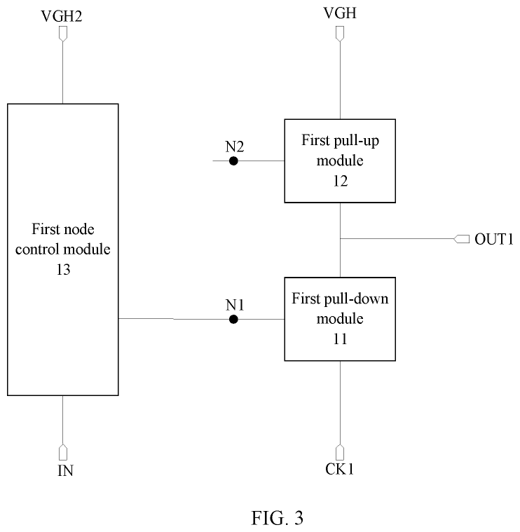

As shown in FIG. 3, a shift register 10 provided by various embodiments of the present application may include a first pull-down module 11. The control terminal of the first pull-down module 11 may be electrically connected to the first node N1, the first terminal of the first pull-down module 11 may be electrically connected to a first clock signal output terminal CK1, and the second terminal of the first pull-down module 11 may be electrically connected to a first output terminal OUT1 of the shift register 10, which may be configured to, in response to the conduction level of the first node N1, to transmit a first clock signal of the first clock signal output terminal CK1 to the first output terminal OUT1 of the shift register 10.

The shift register 10 may further include a first pull-up module 12. The control terminal of the first pull-up module 12 may be electrically connected to the second node N2, the first terminal of the first pull-up module 12 may be electrically connected to a first cut-off level voltage terminal VGH, and the second terminal of the first pull-up module 12 may be electrically connected to the first output terminal OUT1 of the shift register 10, which may be configured to, in response to the conduction level of the second node N2, transmit a first cut-off level signal of the first cut-off level voltage terminal VGH to the first output terminal OUT1 of the shift register 10.

The shift register 10 may further include a first node control module 13. The first node control module 13 may be electrically connected to the first node N1, the input terminal IN of the shift register 10, and a second cut-off level voltage terminal VGH2, which may be configured to, when the first cut-off level signal is outputted by the first output terminal OUT1 of the shift register 10, transmit the second cut-off level voltage signal outputted from the input terminal IN of the shift register 10 or the second cut-off level voltage terminal VGH2 to the first node N1.

In various embodiments of the present application, the voltage value of the second cut-off level voltage signal may be greater than the voltage value of the first cut-off level signal.

For example, in a cut-off level outputting stage t3, the second node N2 may be at the conduction level, the first pull-up module 12 may be in conduction in response to the conduction level of the second node N2, the cut-off level of the first cut-off level voltage terminal VGH may be transmitted to the first output terminal OUT1, and the first output terminal OUT1 may output the cut-off level. In addition, the first node control module 13 may transmit the second cut-off level voltage signal outputted from the input terminal IN of the shift register 10 or the second cut-off level voltage terminal VGH2 to the first node N1, and the first pull-down module 11 may be turned off in response to the cut-off level of the first node N1. Compared with the existing technology, in various embodiments of the present application, the second cut-off level voltage signal with a higher voltage value may be outputted to the first node N1 to increase the gate turn-off voltage of the first pull-down module 11, thereby more thoroughly turning off the first pull-down module 11. Therefore, the influence of the conduction level signal flowing in the first pull-down module 11 on the first cut-off level signal outputted by the shift register may be reduced, and the shift register may be insured to output a stable first cut-off level signal.

In some embodiments, the cut-off level outputting stage t3 may include a first cut-off level outputting stage t31 and a second cut-off level outputting stage t32. For example, in the first cut-off level outputting stage t31, the first node control module 13 may transmit the second cut-off level voltage signal outputted by the input terminal IN of the shift register 10 to the first node N1; and in the second cut-off level outputting stage t32, the first node control module 13 may transmit the second cut-off level voltage signal outputted by the second cut-off level voltage terminal VGH2 to the first node N1, such that the second cut-off level voltage signal with a higher voltage value may be outputted to the first node N1 to increase the gate turn-off voltage of the first pull-down module 11.

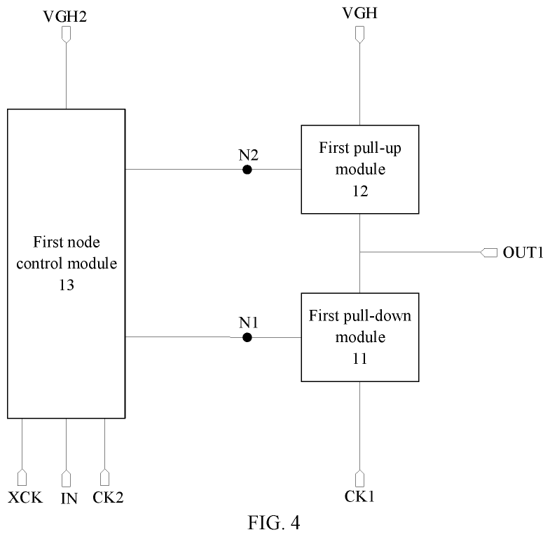

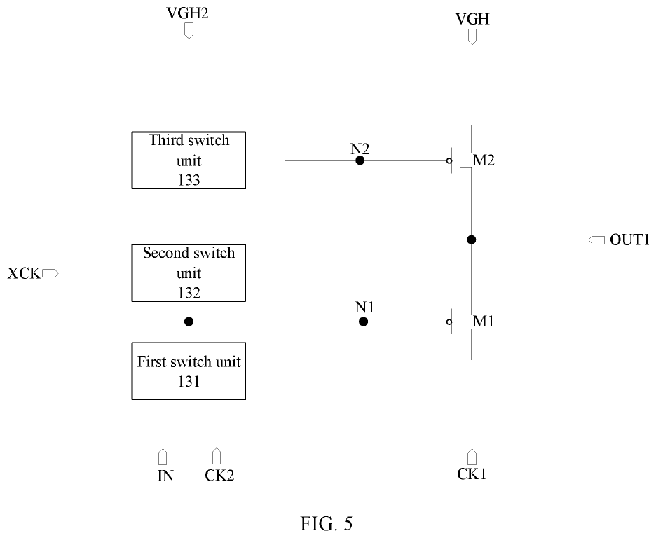

The following is a description with reference to FIGS. 4 and 5. As shown in FIG. 4, in some embodiments, the first node control module 13 may also be electrically connected to a second clock signal output terminal CK2, a third clock signal output terminal XCK, and the second node N2. Exemplarily, in the first cut-off level outputting stage t31, the first node control module 13 may be configured to, in response to the conduction level of the second clock signal output terminal CK2, transmit the second cut-off level voltage signal of the input terminal IN of the shift register 10 to the first node N1. Exemplarily, in the second cut-off level outputting stage t32, the first node control module 13 may be configured to, in response to the conduction levels of the third clock signal output terminal XCK and the second node N2, transmit the second cut-off level voltage signal of the second cut-off level voltage terminal VGH2 to the first node N1.

For example, as shown in FIG. 5, the first pull-down module 11 may include a first transistor M1, the first pull-up module 12 may include a second transistor M2, and the first node control module 13 may include a first switch unit 131, a second switch unit 132, and a third switch unit 133.

The control terminal of the first transistor M1 may be electrically connected to the first node N1, the first terminal of the first transistor M1 may be electrically connected to the first clock signal output terminal CK1, and the second terminal of the first transistor M1 may be electrically connected to the first output terminal OUT1.

The control terminal of the second transistor M2 may be electrically connected to the second node N2, the first terminal of the second transistor M2 may be electrically connected to the first cut-off level voltage terminal VGH, and the second terminal of the second transistor M2 may be electrically connected to the first output terminal OUT1.

The control terminal of the first switch unit 131 may be electrically connected to the second clock signal output terminal CK2, the first terminal of the first switch unit 131 may be electrically connected to the input terminal IN of the shift register 10, and the second terminal of the first switch unit 131 may be electrically connected to the first node N1.

The control terminal of the second switch unit 132 may be electrically connected to the third clock signal output terminal XCK, and the first terminal of the second switch unit 132 may be electrically connected to the first node N1.

The control terminal of the third switch unit 133 may be electrically connected to the second node N2, the first terminal of the third switch unit 133 may be electrically connected to the second cut-off level voltage terminal VGH2, and the second terminal of the third switch unit 133 may be electrically connected to the second terminal of the second switch unit 132.

Exemplarily, in the first cut-off level outputting stage t31, the first switch unit 131 may be in conduction in response to the conduction level of the second clock signal output terminal CK2, thereby transmitting the second cut-off level voltage signal of the input terminal IN of the shift register 10 to the first node N1. In the second cut-off level outputting stage t32, the second switch unit 132 may be in conduction in response to the conduction level of the third clock signal output terminal XCK, and the third switch unit 133 may be in conduction in response to the conduction level of the second node N2, thereby transmitting the second cut-off level voltage signal of the second cut-off level voltage terminal VGH2 to the first node N1. Compared with the existing technology, in various embodiments of the present application, in the first cut-off level outputting stage t31 and the second cut-off level outputting stage t32, the second cut-off level voltage signal with a higher voltage value may be outputted to the first node N1 to increase the gate turn-off voltage of the first pull-down module 11, thereby more thoroughly turning off the first pull-down module 11. Therefore, the influence of the conduction level signal flowing in the first pull-down module 11 on the first cut-off level signal outputted by the shift register may be reduced, and the shift register may be insured to output a stable first cut-off level signal.

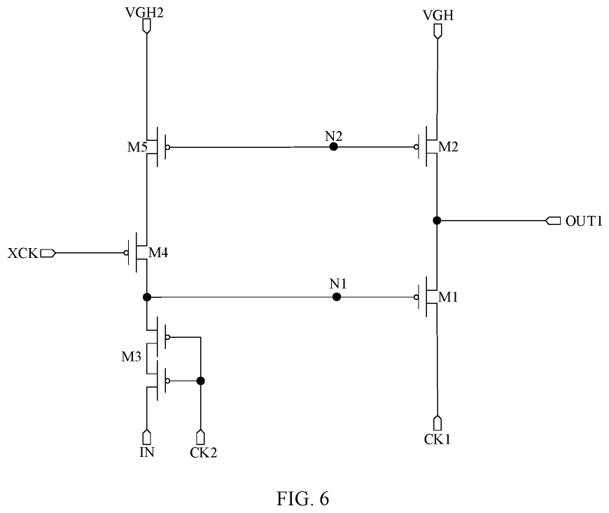

As shown in FIG. 6, in some embodiments, in order to improve the voltage withstanding capability of the first switch unit 131 and circuit stability, the first switch unit 131 may include at least two third transistors M3. At least two third transistors M3 may be arranged in series, and the control terminals of at least two third transistors M3 may both be electrically connected to the second clock signal output terminal CK2. The first terminal of one third transistor M3 of the at least two third transistors M3 may be electrically connected to the input terminal IN of the shift register 10, and the second terminal of the other third transistor M3 may be electrically connected to the first node N1. Compared with a single transistor, by arranging at least two third transistors M3 in series, the voltage withstanding capability of the first switch unit 131 may be improved, which is beneficial for the circuit stability.

Referring to FIG. 6, the second switch unit 132 may include a fourth transistor M4, and the third switch unit 133 may include a fifth transistor M5.

The control terminal of the fourth transistor M4 may be electrically connected to the third clock signal output terminal XCK, and the first terminal of the fourth transistor M4 may be electrically connected to the first node N1.

The control terminal of the fifth transistor M5 may be electrically connected to the second node N2, the first terminal of the fifth transistor M5 may be electrically connected to the second cut-off level voltage terminal VGH2, and the second terminal of the fifth transistor M5 may be electrically connected to the second terminal of the fourth transistor M4.

Exemplarily, in the first cut-off level outputting stage t31, at least two third transistors M3 may be in conduction in response to the conduction level of the second clock signal output terminal CK2, thereby transmitting the second cut-off level voltage signal of the input terminal IN of the shift register 10 to the first node N1. In the second cut-off level outputting stage t32, the fourth transistor M4 may be in conduction in response to the conduction level of the third clock signal output terminal XCK, the fifth transistor M5 may be in conduction in response to the conduction level of the second node N2, and the second cut-off level voltage signal of the second cut-off level voltage terminal VGH2 may be transmitted to the first node N1 via the fourth transistor M4 and the fifth transistor M5. Compared with the existing technology, in various embodiments of the present application, in the first cut-off level outputting stage t31 and the second cut-off level outputting stage t32, the second cut-off level voltage signal with a higher voltage value may be outputted to the first node N1 to increase the gate turn-off voltage of the first transistor M1, thereby more thoroughly turning off the first transistor M1. Therefore, the influence of the conduction level signal flowing in the first transistor M1 on the first cut-off level signal outputted by the shift register 10 may be reduced, and the shift register 10 may be insured to output a stable first cut-off level signal.

Furthermore, in the existing technology, since the output terminal of the shift register is connected to both the gate line of the pixel array and the input terminal of the shift register at a next stage, the load connected to the output terminal of the shift register may be relatively large, which may result in the outputted signal to be delayed, and when the delay is relatively large, the problems including shift register read and write errors and continued transmission failure may occur.

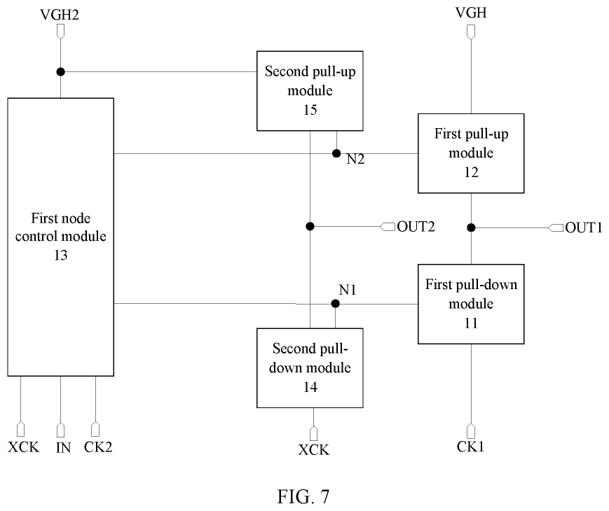

In order to solve the problems of shift register read and write errors and continued transmission failure, as shown in FIG. 7, in some embodiments, the shift register 10 provided in various embodiments of the present application may further include a second pull-down module 14. The control terminal of the second pull-down module 14 may be electrically connected to the first node N1, the first terminal of the second pull-down module 14 may be electrically connected to the third clock signal output terminal XCK, and the second terminal of the second pull-down module 14 may be electrically connected to a second output terminal OUT2 of the shift register 10, which may be configured to, in response to the conduction level of the first node N1, transmit the third clock signal of the third clock signal output terminal XCK to the second output terminal OUT2 of the shift register 10.

The shift register 10 may further include a second pull-up module 15. The control terminal of the second pull-up module 15 may be electrically connected to the second node N2, the first terminal of the second pull-up module 15 may be electrically connected to the second cut-off level voltage terminal VGH2, and the second terminal of the second pull-up module 15 may be electrically connected to the second output terminal OUT2 of the shift register 10, which may be configured to, in response to the conduction level of the second node N2, transmit the second cut-off level voltage signal of the second cut-off level voltage terminal VGH2 to the second output terminal OUT2 of the shift register 10.

The first output terminal OUT1 of the shift register 10 may be electrically connected to the gate line of the pixel array, and the second output terminal OUT2 of the shift register 10 may be electrically connected to the input terminal IN of the shift register at a next stage 10.

In various embodiments of the present application, the second pull-down module 14, the second pull-up module 15 and the second output terminal OUT2 may be added to the shift register. The first output terminal OUT1 of the shift register 10 may provide a driving signal for the gate line of the pixel array, and the second output terminal OUT2 of the shift register 10 may provide a trigger signal for the shift register at a next stage. That is, a same output terminal of the shift register 10 may be avoided to be responsible for both driving the gate line and providing a trigger signal for the shift register at a next stage. Since the second output terminal OUT2 of the shift register 10 only provides a trigger signal for the shift register at a next stage and no longer drives the gate line, the load connected to the second output terminal OUT2 of the shift register 10 may be reduced, and the delay of the signal outputted by the second output terminal OUT2 of the shift register 10 may be relative small, which may avoid the problems of shift register read and write errors and continued transmission failure caused by signal delay, thereby improving the circuit stability.

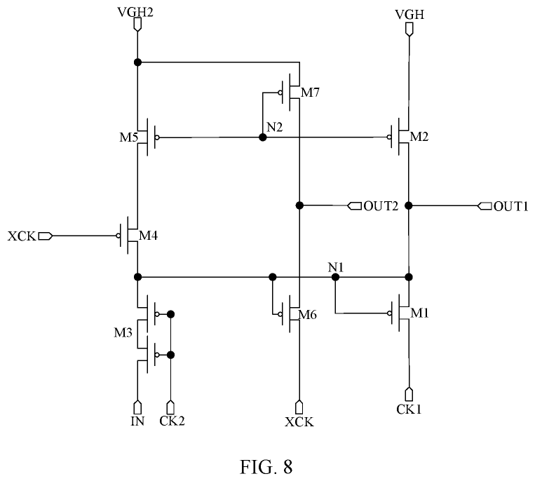

As shown in FIG. 8, in some embodiments, the second pull-down module 14 may include a sixth transistor M6, and the second pull-up module 15 may include a seventh transistor M7.

The control terminal of the sixth transistor M6 may be electrically connected to the first node N1, the first terminal of the sixth transistor M6 may be electrically connected to the third clock signal output terminal XCK, and the second terminal of the sixth transistor M6 may be electrically connected to the second output terminal OUT2 of the shift register 10.

The control terminal of the seventh transistor M7 may be electrically connected to the second node N2, the first terminal of the seventh transistor M7 may be electrically connected to the second cut-off level voltage terminal VGH2, and the second terminal of the seventh transistor M7 may be electrically connected to the second output terminal OUT2 of the shift register 10.

In various embodiments of the present application, the sixth transistor M6, the seventh transistor M7, and the second output terminal OUT2 may be added to the shift register. The first output terminal OUT1 of the shift register 10 may provide a driving signal for the gate line of the pixel array, and the second output terminal OUT2 of the shift register 10 may provide a trigger signal for the shift register at a next stage. That is, a same output terminal of the shift register 10 may be avoided to be responsible for both driving the gate line and providing a trigger signal for the shift register at a next stage. Since the second output terminal OUT2 of the shift register 10 only provides a trigger signal for the shift register at a next stage, and no longer drives the gate line, the load connected to the second output terminal OUT2 of the shift register 10 may be reduced, and the delay of the signal outputted by the second output terminal OUT2 of the shift register 10 may be relative small, which may avoid the problems of shift register read and write errors and continued transmission failure caused by signal delay, thereby improving the circuit stability.

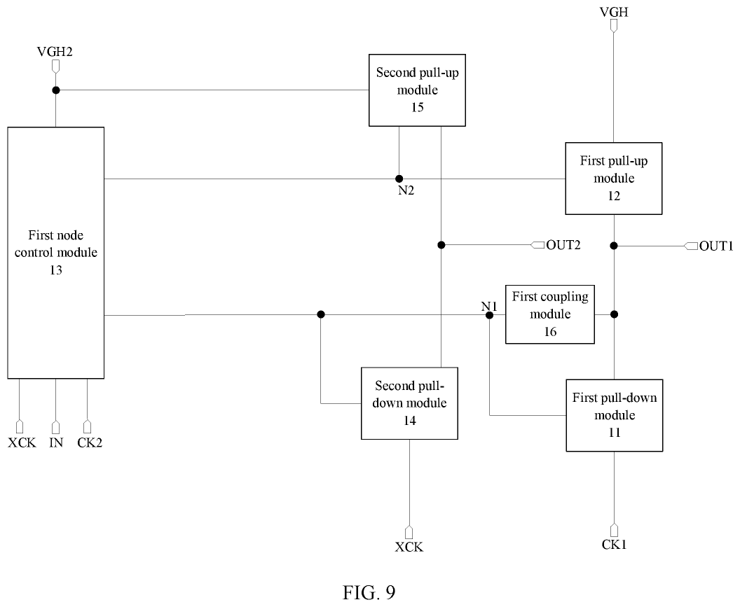

In order to ensure that the first output terminal OUT1 of the shift register 10 can output a conduction level signal with a lower voltage value, as shown in FIG. 9, the shift register 10 provided in various embodiments of the present application may further include a first coupling module 16. The first terminal of the first coupling module 16 may be electrically connected to the first node N1, and the second terminal of the first coupling module 16 may be electrically connected to the first output terminal OUT1 of the shift register 10.

For example, in the conduction level outputting stage t2, the first node N1 may be at the conduction level, the first output terminal OUT1 of the shift register 10 may be switched from outputting a cut-off level signal to outputting a conduction level signal (shifting to a low level), and under the bootstrap action of the first coupling module 16, the potential of the first node N1 may be further pulled down to a lower level through the coupling. As a result, the first pull-down module 11 may be turned on more sufficiently, thereby ensuring that the first output terminal OUT1 of the shift register 10 may output a conduction level signal with a relatively low voltage value.

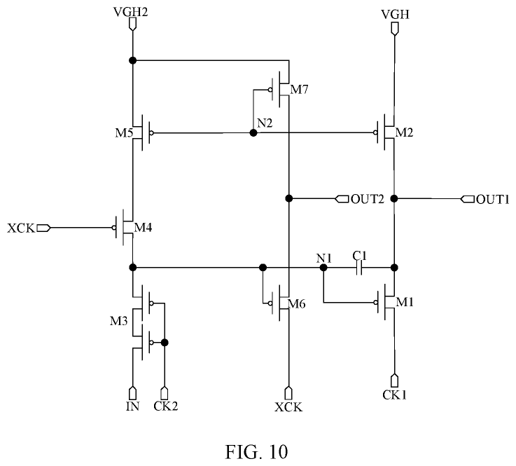

As shown in FIG. 10, in some embodiments, the first coupling module 16 may include a first coupling capacitor C1. The first plate of the first coupling capacitor C1 may be electrically connected to the first node N1, and the second plate of the first coupling capacitor C1 may be electrically connected to the first output terminal OUT1 of the shift register 10. By setting the first coupling capacitor C1, the potential of the first node N1 may be further lowered to a lower level through coupling under the bootstrap action of the first coupling capacitor C1 in the conduction level outputting stage t2. As a result, the first pull-down module 11 may be turned on more sufficiently, thereby ensuring that the first output terminal OUT1 of the shift register 10 may output a conduction level signal with a relatively low voltage value.

As mentioned above, when the first output terminal OUT1 of the shift register 10 switches from outputting a cut-off level signal to outputting a conduction level signal (shifting to a low level), the first node N1 may be pulled down from a relatively low potential to a lower potential. Since the first node N1 is pulled down to a lower potential, the voltage difference between the gate electrode and the drain electrode or the gate electrode and the source electrode of the transistor connected to the first node N1 may become large, which may increase the degree of the threshold drift of the transistor to make the circuit stability worse.

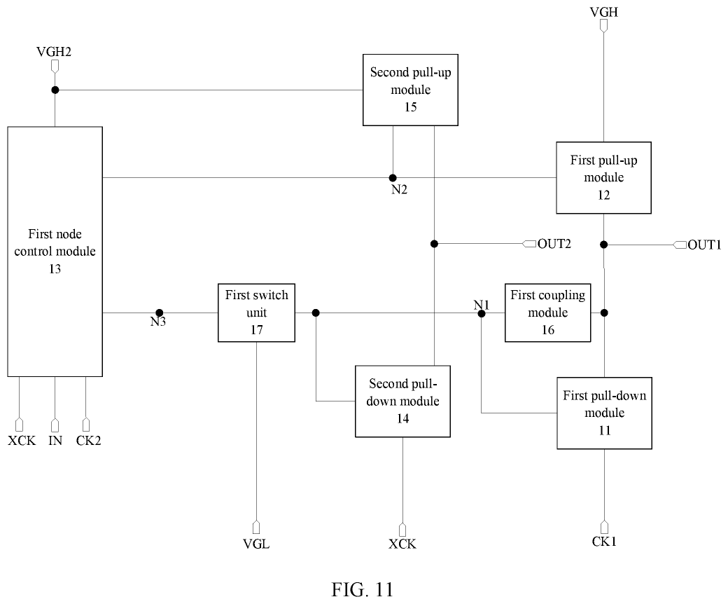

In order to solve above-mentioned problem, as shown in FIG. 11, in some embodiments, the shift register 10 provided in various embodiments of the present application may further include a first switch module 17. The control terminal of the first switch module 17 may be electrically connected to the conduction level voltage terminal VGL, the first terminal of the first switch module 17 may be electrically connected to the first node control module 13, and the second terminal of the first switch module 17 may be electrically connected to the first node N1, which may be configured to disconnect the electrical connection between the first node N1 and the first node control module 13 in the conduction level outputting stage t2. By setting the first switch module 17 between the first node N1 and the first node control module 13, and turning off the first switch module 17 in the conduction level outputting stage t2, the potentials of the gate electrode, source electrode, or drain electrode of the transistors connected to the first node N1 (e.g., the third transistor M3 and the fourth transistor M4) may not be further reduced as the potential of the first node N1 decreases. Therefore, the voltage difference between the gate electrode and the drain electrode or the gate electrode and the source electrode of each transistor connected to the first node N1 may be reduced to improve the circuit stability.

For example, in the conduction level outputting stage t2, the first node N1 may be at the conduction level, and the first output terminal OUT1 of the shift register 10 may be switched from outputting a cut-off level signal to outputting a conduction level signal (shifting to a low level), and under the bootstrap action of the first coupling module 16, the potential of the first node N1 may be pulled down to an extremely low level. Without the first switch module 17, the voltage difference between the gate electrode and the drain electrode or the gate electrode and the source electrode of each transistor connected to the first node N1 may be relatively large. As a result, the threshold drift of the transistor connected to the first node N1 may be more severely to have poor circuit stability. After adding the first switch module 17, affected by the switching characteristics of the transistor itself, when the difference between the voltage value V_{g} of the control terminal of the first switch module 17 and the voltage value Vₛ of the second terminal of the first switch module 17 is less than or equal to the absolute value |Vₜₕ| of the threshold voltage of the first switch module 17, that is, when V_{g}−Vₛ≤|Vₜₕ|, the first switch module 17 may be turned off. In such way, the potentials of the gate electrode, source electrode, or drain electrode of the transistor connected to the first terminal of the first switch module 17 may not continue to be pulled down. Therefore, the voltage difference between the gate electrode and the drain electrode or the gate electrode and the source electrode of the transistor connected to the first terminal of the first switch module 17 may be reduced to improve the circuit stability. V_{g} is equal to the voltage value of the conduction level outputted from the conduction level voltage terminal VGL, and Vₛ is equal to the voltage value of the conduction level outputted by the first output terminal OUT1 of the shift register 10 after being coupled by the first coupling module 16.

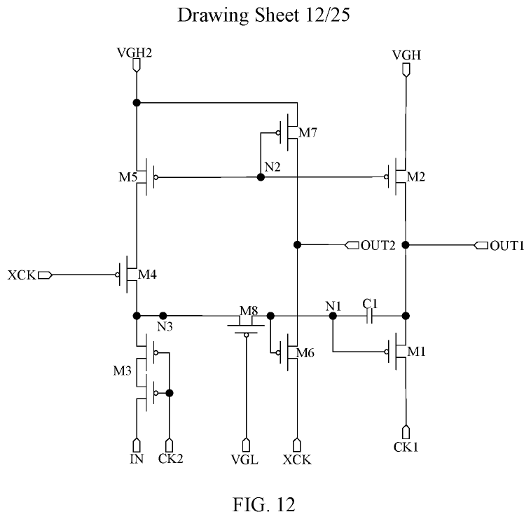

As shown in FIG. 12, in some embodiments, the first switch module 17 may include an eighth transistor M8. The control terminal of the eighth transistor M8 may be electrically connected to the conduction level voltage terminal VGL, the first terminal of the eighth transistor M8 may be electrically connected to the first node control module 13, and the second terminal of the eighth transistor M8 may be electrically connected to the first node N1. In the conduction level outputting stage t2, affected by the switching characteristics of the transistor itself, when the difference between the voltage value V_{g} of the control terminal of the eighth transistor M8 and the voltage value Vₛ of the second terminal of the eighth transistor M8 is less than or equal to the absolute value |Vₜₕ| of the threshold voltage of the eighth transistor M8, that is, when V_{g}−Vₛ≤|Vₜₕ|, the eighth transistor M8 may be turned off. In such way, the potentials of the gate electrode, source electrode or drain electrode of the transistor connected to the first terminal of the eighth transistor M8 (e.g., the source electrode or drain electrode of the third transistor M3, or the source electrode or drain electrode of the fourth transistor M4) may not continue to be pulled down. Therefore, the voltage difference between the gate electrode and the drain electrode or the gate electrode and the source electrode of the transistor connected to the first terminal of the eighth transistor M8 may be reduced to improve the circuit stability.

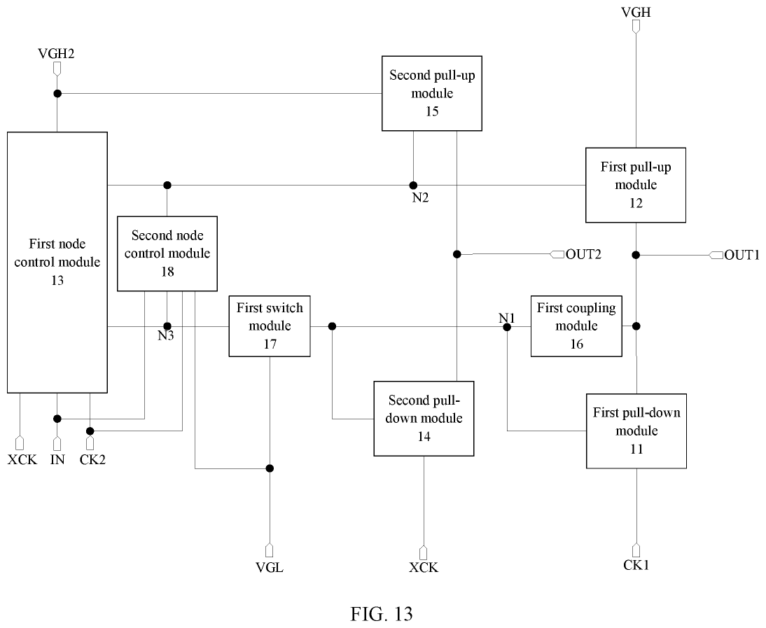

As shown in FIG. 13, in order to facilitate the potential control of the second node N2, in some embodiments, the shift register 10 provided in various embodiments of the present application may further include a second node control module 18. The second node control module 18 may be electrically connected to a third node N3, the second clock signal output terminal CK2, the conduction level voltage terminal VGL, the input terminal IN of the shift register 10, and the second node N2, which may be configured to, in response to the conduction level of the second clock signal output terminal CK2, transmit the conduction level voltage signals inputted from the input terminal IN and the conduction level voltage terminal VGL of the shift register 10 to the second node N2; and may also be configured to, in response to the conduction level of the third node N3, transmit the second cut-off level voltage signal inputted from the input terminal IN of the shift register 10 to the second node N2. The third node N3 may be any node between the first node control module 13 and the first switch module 17.

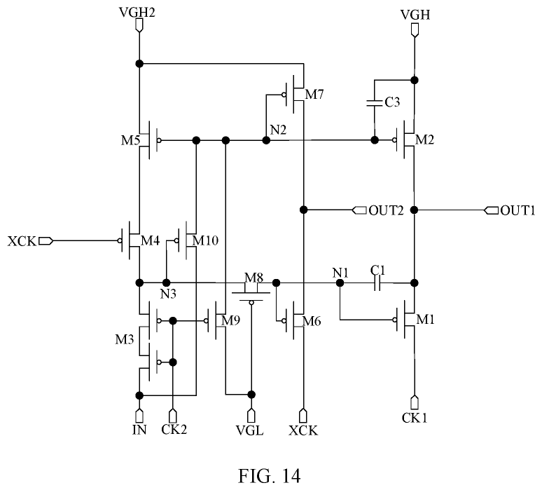

As shown in FIG. 14, in some embodiments, the second node control module 18 may include a ninth transistor M9. The control terminal of the ninth transistor M9 may be electrically connected to the second clock signal output terminal CK2, the first terminal of the ninth transistor M9 may be electrically connected to the conduction level voltage terminal VGL, and the second terminal of the ninth transistor M9 may be electrically connected to the second node N2.

The second node control module 18 may further include a tenth transistor M10. The control terminal of the tenth transistor M10 may be electrically connected to the third node N3, the first terminal of the tenth transistor M10 may be electrically connected to the input terminal IN of the shift register 10, and the second terminal of the tenth transistor M10 may be electrically connected to the second node N2.

For example, in a cut-off level maintaining stage t1, the input terminal IN of the shift register 10, the second clock signal output terminal CK2, and the conduction level voltage terminal VGL may all output the conduction levels; the ninth transistor M9 may be in conduction in response to the conduction level of the second clock signal output terminal CK2, thereby transmitting the conduction level outputted by the conduction level voltage terminal VGL to the second node N2; and the tenth transistor M10 may be in conduction in response to the conduction level of the third node N3, thereby transmitting the conduction level outputted by the input terminal IN of the shift register 10 to the second node N2. For example, in a conduction level outputting stage t2, the input terminal IN of the shift register 10 may output the second cut-off level signal, and the second clock signal output terminal CK2 may output the first cut-off level signal; and the ninth transistor M9 may be turned off in response to the cut-off level of the second clock signal output terminal CK2, and the tenth transistor M10 may be in conduction in response to the conduction level of the third node N3, thereby transmitting the second cut-off level signal outputted from the input terminal IN of the shift register 10 to the second node N2. For example, in the first cut-off level outputting stage t31, the input terminal IN of the shift register 10 may output the second cut-off level signal, and the second clock signal output terminal CK2 and the conduction level voltage terminal VGL may both output the conduction levels; and the tenth transistor M10 may be turned off in response to the cut-off level of the third node N3, and the ninth transistor M9 may be in conduction in response to the conduction level of the second clock signal output terminal CK2, thereby transmitting the conduction level outputted from the conduction level voltage terminal VGL to the second node N2.

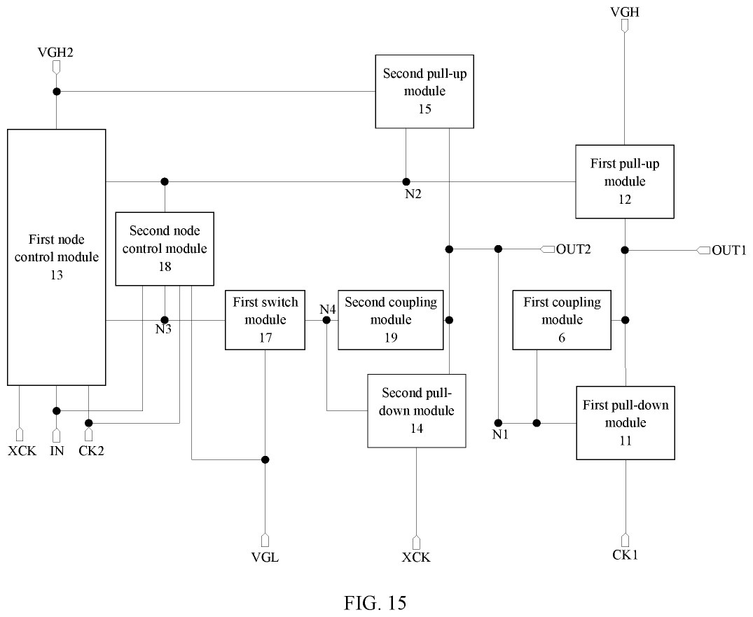

In order to ensure that the second output terminal OUT2 of the shift register 10 can output a conduction level signal with a lower voltage value, as shown in FIG. 15, the shift register 10 provided in various embodiments of the present application may further include a second coupling module 19. The first terminal of the second coupling module 19 may be electrically connected to the control terminal of the second pull-down module 14, and the second terminal of the second coupling module 19 may be electrically connected to the second terminal of the second pull-down module 14.

For example, in the conduction level outputting stage t2, the second output terminal OUT2 of the shift register 10 may be switched from outputting a cut-off level signal to outputting a conduction level signal (shifting to a low level), and under the bootstrap action of the second coupling module 19, the potential of the control terminal of the second pull-down module 14 may be further pulled down to a lower level through coupling. As a result, the second pull-down module 14 may be turned on more sufficiently, thereby ensuring that the second output terminal OUT2 of the shift register 10 may output a conduction level signal with a lower voltage value.

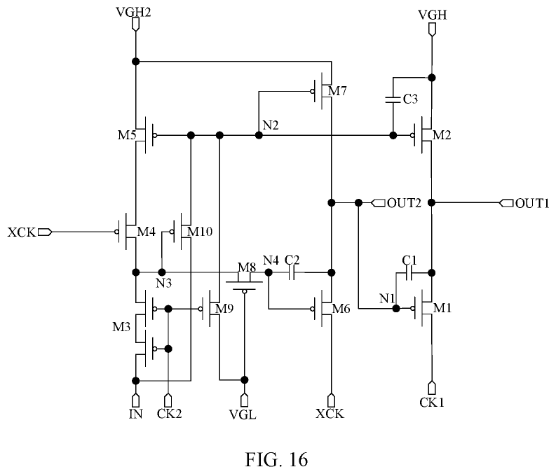

As shown in FIG. 16, in some embodiments, the second coupling module 19 may include a second coupling capacitor C2. The first plate of the second coupling capacitor C2 may be electrically connected to the control terminal of the second pull-down module 14, and the second plate of the second coupling capacitor C2 may be electrically connected to the second terminal of the second pull-down module 14. For example, when the second pull-down module 14 includes the sixth transistor M6, the first plate of the second coupling capacitor C2 may be electrically connected to the control terminal of the sixth transistor M6, and the second plate of the second coupling capacitor C2 may be electrically connected to the second terminal of the sixth transistor M6.

In the conduction level outputting stage t2, the second output terminal OUT2 of the shift register 10 may be switched from outputting a cut-off level signal to outputting a conduction level signal (shifting to a low level), and under the bootstrap action of the second coupling capacitor C2, the potential of the control terminal of the sixth transistor M6 may be further pulled down to a lower level through the coupling. As a result, the sixth transistor M6 may be turned on more sufficiently, thereby ensuring that the second output terminal OUT2 of the shift register 10 may output a conduction level signal with a lower voltage value.

After the second coupling capacitor C2 is added between the first node control module 13 and the first node N1, the first node control module 13 and the first node N1 may be disconnected. Therefore, in order to normally control the potential of the first node N1, as shown in FIG. 16, the first node N1 may be electrically connected to the second output terminal OUT2 of the shift register 10. In such way, the potential of the first node N1 may be controlled by the level signal outputted from the second output terminal OUT2 of the shift register 10. The second output terminal OUT2 and the first output terminal OUT1 of the shift register 10 may simultaneously output the cut-off levels and the conduction levels, the second output terminal OUT2 and the first output terminal OUT1 may output the level signals at a same timing, such that the control timing of the first node N1 may not need to be changed.

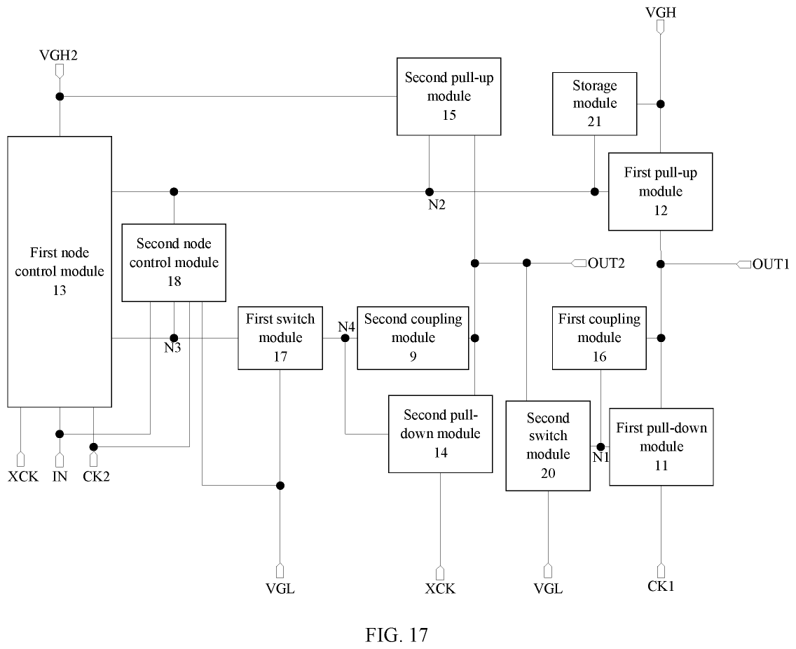

In order to ensure that the second output terminal OUT2 of the shift register 10 can output a stable cut-off level signal, as shown in FIG. 17, in some embodiments, the shift register 10 provided in various embodiments of the present application may further include a second switch module 20. The control terminal of the second switch module 20 may be electrically connected to the conduction level voltage terminal VGL, the first terminal of the second switch module 20 may be electrically connected to the second output terminal OUT2 of the shift register 10 and the second terminal of the second coupling module 19 respectively, and the second terminal of the second switch module 20 may be electrically connected to the first node N1, which may be configured to disconnect the electrical connection between the second coupling module 19 and the first node N1 in the conduction level outputting stage t2. On the one hand, in the conduction level outputting stage t2, the second switch module 20 may be turned off, and the electrical connection between the second output terminal OUT2 and the first coupling module 16 may be disconnected, which may avoid the influence of the coupling of the first coupling module 16 on the cut-off level signal outputted by the second output terminal OUT2 and ensure that the second output terminal OUT2 of the shift register 10 can output a stable cut-off level signal. On the other hand, in the conduction level outputting stage t2, the second switch module 20 may be turned off, and the electrical connection between the second coupling module 19 and the first coupling module 16 may be disconnected, which may avoid the coupling voltage division of the first coupling module 16 when the second coupling module 19 is coupled, and ensure that the potential of the control terminal of the second pull-down module 14 is pulled down to a lower level. As a result, the second pull-down module 14 may be turned on more sufficiently, thereby ensuring that the second output terminal OUT2 of the shift register 10 can output a conduction level signal with a lower voltage value.

For example, in the conduction level outputting stage t2, affected by the switching characteristics of the transistor itself, when the difference between the voltage value V_{g}′ of the control terminal of the second switch module 20 and the voltage value Vₛ′ of the second terminal of the second switch module 20 is less than or equal to the absolute value |Vₜₕ|′ of the threshold voltage of the second switch module 20, that is, when V_{g}′−Vₛ′≤|Vₜₕ|′, the second switch module 20 may be turned off. Therefore, the electrical connection between the second coupling module 19 and the first node N1 may be disconnected, and the electrical connection between the second output terminal OUT2 and the first node N1 may be disconnected. V_{g}′ is equal to the voltage value of the conduction level outputted from the conduction level voltage terminal VGL, and Vₛ′ is equal to the voltage value of the conduction level outputted by the first output terminal OUT1 of the shift register 10 after being coupled by the first coupling module 16.

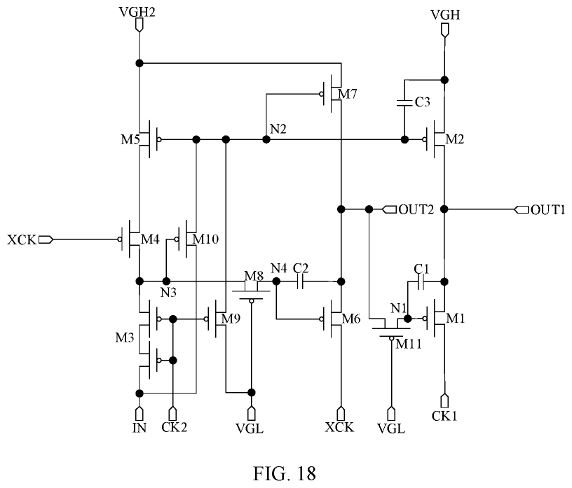

As shown in FIG. 18, in some embodiments, the second switch module 20 may include an eleventh transistor M11. The control terminal of the eleventh transistor M11 may be electrically connected to the conduction level voltage terminal VGL; the first terminal of the eleventh transistor M11 may be electrically connected to the second output terminal OUT2 of the shift register 10 and the second plate of the second coupling capacitor C2, respectively; and the second terminal of the eleventh transistor M11 may be electrically connected to the first node N1. In the conduction level outputting stage t2, affected by the switching characteristics of the transistor itself, when the difference between the voltage value V_{g}′ of the control terminal of the eleventh transistor M11 and the voltage value Vₛ′ of the second terminal of the eleventh transistor M11 is less than or equal to the absolute value |Vₜₕ|′ of the threshold voltage of the eleventh transistor M11, that is, when V_{g}′−Vₛ′≤|Vₜₕ|′, the eleventh transistor M11 may be turned off. Therefore, the electrical connection between the second coupling capacitor C2 and the first node N1 may be disconnected, and the electrical connection between the second output terminal OUT2 and the first node N1 may be disconnected.

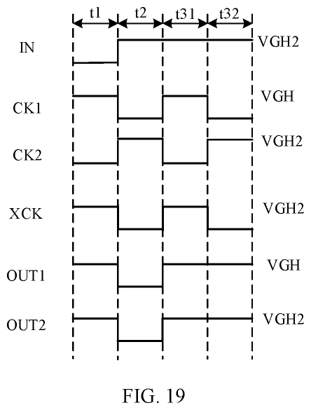

FIG. 19 illustrates an exemplary timing diagram of the shift register according to various embodiments of the present disclosure. As shown in FIGS. 14 and 19, in some embodiments, the driving process of the shift register may include the following stages: the cut-off level maintaining stage t1, the conduction level outputting stage t2, and the cut-off level outputting stage t3. The cut-off level outputting stage t3 may further include the first cut-off level outputting stage t31 and the second cut-off level outputting stage t32.

In the cut-off level maintaining stage t1, the input terminal IN of the shift register 10, the second clock signal output terminal CK2 and the conduction level voltage terminal VGL may output the conduction levels; and the first clock signal output terminal CK1, the third clock signal output terminal XCK and the first cut-off level voltage terminal VGH may output the cut-off levels. The third transistor M3 may be in conduction in response to the conduction level of the second clock signal output terminal CK2, and transmit the conduction level outputted by the input terminal IN of the shift register 10 to the third node N3; and the eighth transistor M8 may be in conduction in response to the conduction level of the conduction level voltage terminal VGL, and transmit the conduction level of the third node N3 to the first node N1. The ninth transistor M9 may be in conduction in response to the conduction level of the second clock signal output terminal CK2, and transmit the conduction level outputted by the conduction level voltage terminal VGL to the second node N2. The tenth transistor M10 may be in conduction in response to the conduction level of the third node N3, and transmit the conduction level outputted by the input terminal IN of the shift register 10 to the second node N2. The first transistor M1 may be in conduction in response to the conduction level of the first node N1, and transmit the first cut-off level signal of the first clock signal output terminal CK1 to the first output terminal OUT1 of the shift register 10. The second transistor M2 may be in conduction in response to the conduction level of the second node N2, and transmit the first cut-off level signal of the first cut-off level voltage terminal VGH to the first output terminal OUT1 of the shift register 10. The first output terminal OUT1 of the shift register 10 may output the first cut-off level signal. The sixth transistor M6 may be in conduction in response to the conduction level of the first node N1, and transmit the cut-off level of the third clock signal output terminal XCK to the second output terminal OUT2 of the shift register 10. The seventh transistor M7 may be in conduction in response to the conduction level of the second node N2, and transmit the second cut-off level signal of the second cut-off level voltage terminal VGH2 to the second output terminal OUT2 of the shift register 10. The second output terminal OUT2 of the shift register 10 may output the second cut-off level signal. The first coupling capacitor C1 may store the conduction levels of the first node N1 and the third node N3.

In the conduction level outputting stage t2, the first clock signal output terminal CK1, the third clock signal output terminal XCK, and the conduction level voltage terminal VGL may output the conduction levels, the input terminal IN of the shift register 10 may output the second cut-off level signal, and the second clock signal output terminal CK2 and the first cut-off level voltage terminal VGH may output the cut-off levels. The first coupling capacitor C1 may maintain the first node N1 and the third node N3 at the conduction levels. The tenth transistor M10 may be in conduction in response to the conduction level of the third node N3, and transmit the second cut-off level signal outputted from the input terminal IN of the shift register 10 to the second node N2. The first transistor M1 may be in conduction in response to the conduction level of the first node N1, and transmit the conduction level signal of the first clock signal output terminal CK1 to the first output terminal OUT1 of the shift register 10. The second transistor M2 may be turned off in response to the cut-off level of the second node N2. The first output terminal OUT1 of the shift register 10 may output the conduction level signal. The sixth transistor M6 may be in conduction in response to the conduction level of the first node N1, and transmit the conduction level of the third clock signal output terminal XCK to the second output terminal OUT2 of the shift register 10. The seventh transistor M7 may be turned off in response to the cut-off level of the second node N2. The second output terminal OUT2 of the shift register 10 may output the conduction level signal.

Furthermore, in the conduction level outputting stage t2, the potential of the first node N1 may be further pulled down to a lower level through the coupling under the bootstrap action of the first coupling capacitor C1, such that the first pull-down module 11 may be turned on more sufficiently, thereby ensuring that the first output terminal OUT1 of the shift register 10 can output a conduction level signal with a lower voltage value.

In the conduction level outputting stage t2, affected by the switching characteristics of the transistor itself, when the difference between the voltage value V_{g} of the control terminal of the eighth transistor M8 and the voltage value Vₛ of the second terminal of the eighth transistor M8 is less than or equal to the absolute value |Vₜₕ| of the threshold voltage of the eighth transistor M8, that is, when V_{g}−Vₛ≤|Vₜₕ|, the eighth transistor M8 may be turned off. Therefore, the potentials of the gate electrode, source electrode or drain electrode of the transistor connected to the first terminal (e.g., the third node N3) of the eighth transistor M8 (e.g., the source electrode or drain electrode of the third transistor M3, or the source electrode or the drain electrode of the fourth transistor M4) may not continue to be pulled down, thereby reducing the voltage difference between the gate electrode and the drain electrode or the gate electrode and the source electrode of the transistor connected to the first terminal of the eighth transistor M8 to improve the circuit stability.

In the first cut-off level outputting stage t31, the second clock signal output terminal CK2 and the conduction level voltage terminal VGL may output the conduction levels; the input terminal IN of the shift register 10 may output the second cut-off level signal; and the first clock signal output terminal CK1, the third clock signal output terminal XCK and the first cut-off level voltage terminal VGH may output the cut-off levels. The third transistor M3 maybe in conduction in response to the conduction level of the second clock signal output terminal CK2, and transmit the second cut-off level signal outputted by the input terminal IN of the shift register 10 to the third node N3; and the eighth transistor M8 may be in conduction in response to the conduction level of the conduction level voltage terminal VGL, and transmit the second cut-off level signal of the third node N3 to the first node N1. The ninth transistor M9 may be in conduction in response to the conduction level of the second clock signal output terminal CK2, and transmit the conduction level outputted by the conduction level voltage terminal VGL to the second node N2. The tenth transistor M10 may be turned off in response to the cut-off level of the third node N3. The first transistor M1 may be turned off in response to the second cut-off level signal of the first node N1. The second transistor M2 may be in conduction in response to the conduction level of the second node N2, and transmit the first cut-off level signal of the first cut-off level voltage terminal VGH to the first output terminal OUT1 of the shift register 10. The first output terminal OUT1 of the shift register 10 may output the first cut-off level signal. The sixth transistor M6 may be turned off in response to the second cut-off level signal of the first node N1. The seventh transistor M7 may be in conduction in response to the conduction level of the second node N2, and transmit the second cut-off level signal of the second cut-off level voltage terminal VGH2 to the second output terminal OUT2 of the shift register 10. The second output terminal OUT2 of the shift register 10 may output the second cut-off level signal. The first storage capacitor C3 may store the conduction level of the second node N2.

Compared with the existing technology, in various embodiments of the present application, the second cut-off level voltage signal with a higher voltage value may be outputted to the first node N1 in the first cut-off level outputting stage t31, such that the gate turn-off voltages of the first transistor M1 and the sixth transistor M6 may be increased to turn off the first transistor M1 and the sixth transistor M6 more thoroughly. Therefore, the influence of the conduction level signal flowing in the first transistor M1 on the first cut-off level signal outputted by the shift register may be reduced, and the shift register may be ensured to output a stable first cut-off level signal; and the influence of the conduction level signal flowing in the sixth transistor M6 on the second cut-off level signal outputted by the shift register may be reduced, and the shift register may be ensured to output a stable second cut-off level signal.

In the second cut-off level outputting stage t32, the third clock signal output terminal XCK and the conduction level voltage terminal VGL may output the conduction levels, the second cut-off level voltage terminal VGH2 may output the second cut-off level signal, and the second clock signal output terminal CK2 and the first cut-off level voltage terminal VGH may output the cut-off levels. The fourth transistor M4 may be in conduction in response to the conduction level of the third clock signal output terminal XCK, the fifth transistor M5 may be in conduction in response to the conduction level of the second node N2, and the second cut-off level signal outputted from the second cut-off level voltage terminal VGH2 may be transmitted to the third node N3 via the fourth transistor M4 and the fifth transistor M5. The eighth transistor M8 may be in conduction in response to the conduction level of the conduction level voltage terminal VGL, and transmit the second cut-off level signal of the third node N3 to the first node N1. The first storage capacitor C3 may maintain the second node N2 at the conduction level. The first transistor M1 may be turned off in response to the second cut-off level signal of the first node N1. The second transistor M2 may be in conduction in response to the conduction level of the second node N2, and transmit the first cut-off level signal of the first cut-off level voltage terminal VGH to the first output terminal OUT1 of the shift register 10. The first output terminal OUT1 of the shift register 10 may output the first cut-off level signal. The sixth transistor M6 may be turned off in response to the second cut-off level signal of the first node N1. The seventh transistor M7 may be in conduction in response to the conduction level of the second node N2, and transmit the second cut-off level signal of the second cut-off level voltage terminal VGH2 to the second output terminal OUT2 of the shift register 10. The second output terminal OUT2 of the shift register 10 may output the second cut-off level signal.

Compared with the existing technology, in various embodiments of the present application, the second cut-off level voltage signal with a higher voltage value may be outputted to the first node N1 in the second cut-off level outputting stage t32, such that the gate turn-off voltages of the first transistor M1 and the sixth transistor M6 may be increased to turn off the first transistor M1 and the sixth transistor M6 more thoroughly. Therefore, the influence of the conduction level signal flowing in the first transistor M1 on the first cut-off level signal outputted by the shift register may be reduced, and the shift register may be ensured to output a stable first cut-off level signal; and the influence of the conduction level signal flowing in the sixth transistor M6 on the second cut-off level signal outputted by the shift register may be reduced, and the shift register may be ensured to output a stable second cut-off level signal.

FIG. 19 may also be a timing diagram of the shift register shown in FIG. 18. As shown in FIGS. 18-19, in various embodiments of the present disclosure, the driving process of the shift register may include the following stages: the cut-off level maintaining stage t1, the conduction level outputting stage t2, and the cut-off level outputting stage t3. The cut-off level outputting stage t3 may further include the first cut-off level outputting stage t31 and the second cut-off level outputting stage t32.

In the cut-off level maintaining stage t1, the input terminal IN of the shift register 10, the second clock signal output terminal CK2 and the conduction level voltage terminal VGL may output the conduction levels; and the first clock signal output terminal CK1, the third clock signal output terminal XCK and the first cut-off level voltage terminal VGH may output the cut-off levels. The third transistor M3 may be in conduction in response to the conduction level of the second clock signal output terminal CK2, and transmit the conduction level outputted by the input terminal IN of the shift register 10 to the third node N3; and the eighth transistor M8 may be in conduction in response to the conduction level of the conduction level voltage terminal VGL, and transmit the conduction level of the third node N3 to a fourth node N4. The ninth transistor M9 may be in conduction in response to the conduction level of the second clock signal output terminal CK2, and transmit the conduction level outputted by the conduction level voltage terminal VGL to the second node N2. The tenth transistor M10 may be in conduction in response to the conduction level of the third node N3, and transmit the conduction level outputted by the input terminal IN of the shift register 10 to the second node N2. The sixth transistor M6 may be in conduction in response to the conduction level of the fourth node N4, and transmit the cut-off level of the third clock signal output terminal XCK to the second output terminal OUT2 of the shift register 10. The seventh transistor M7 may be in conduction in response to the conduction level of the second node N2, and transmit the second cut-off level signal of the second cut-off level voltage terminal VGH2 to the second output terminal OUT2 of the shift register 10. The second output terminal OUT2 of the shift register 10 may output the second cut-off level signal. The eleventh transistor M11 may be in conduction in response to the conduction level of the conduction level voltage terminal VGL, and transmit the second cut-off level signal of the second output terminal OUT2 of the shift register 10 to the first node N1. The first transistor M1 may be turned off in response to the cut-off level of the first node N1. The second transistor M2 may be in conduction in response to the conduction level of the second node N2, and transmit the first cut-off level signal of the first cut-off level voltage terminal VGH to the first output terminal OUT1 of the shift register 10. The first output terminal OUT1 of the shift register 10 may output the first cut-off level signal. The first coupling capacitor C1 may store the conduction level of the first node N1. The first storage capacitor C3 may store the conduction levels of the third node N3 and the fourth node N4.

In the conduction level outputting stage t2, the first clock signal output terminal CK1, the third clock signal output terminal XCK and the conduction level voltage terminal VGL may output the conduction levels, the input terminal IN of the shift register 10 may output the second cut-off level signal, and the second clock signal output terminal CK2 and the first cut-off level voltage terminal VGH may output the cut-off levels. The tenth transistor M10 may be in conduction in response to the conduction level of the third node N3, and transmit the second cut-off level signal outputted from the input terminal IN of the shift register 10 to the second node N2. The sixth transistor M6 may be in conduction in response to the conduction level of the fourth node N4, and transmit the conduction level of the third clock signal output terminal XCK to the second output terminal OUT2 of the shift register 10. The seventh transistor M7 may be turned off in response to the cut-off level of the second node N2. The second output terminal OUT2 of the shift register 10 may output the conduction level signal. The eleventh transistor M11 may be in conduction in response to the conduction level of the conduction level voltage terminal VGL, and transmit the conduction level of the second output terminal OUT2 of the shift register 10 to the first node N1. The first transistor M1 may be in conduction in response to the conduction level of the first node N1, and transmit the conduction level signal of the first clock signal output terminal CK1 to the first output terminal OUT1 of the shift register 10. The second transistor M2 may be turned off in response to the cut-off level of the second node N2. The first output terminal OUT1 of the shift register 10 may output the conduction level signal.

Furthermore, in the conduction level outputting stage t2, the potential of the first node N1 may be further pulled down to a lower level through the coupling under the bootstrap action of the first coupling capacitor C1. As a result, the first pull-down module 11 may be turned on more sufficiently, thereby ensuring that the first output terminal OUT1 of the shift register 10 can output a conduction level signal with a lower voltage value.

In the conduction level outputting stage t2, the second output terminal OUT2 of the shift register 10 may switch from outputting the cut-off level signal to outputting the conduction level signal (shifting to a low level); and under the bootstrap action of the second coupling capacitor C2, the potential of the control terminal of the sixth transistor M6 may be further pulled down to a lower level through the coupling. As a result, the sixth transistor M6 may be turned on more sufficiently, thereby ensuring that the second output terminal OUT2 of the shift register 10 can output a conduction level signal with a lower voltage value.

In the conduction level outputting stage t2, affected by the switching characteristics of the transistor itself, when the difference between the voltage value V_{g}′ of the control terminal of the eleventh transistor M11 and the voltage value Vₛ′ of the second terminal of the eleventh transistor M11 is less than or equal to the absolute value |Vₜₕ|′ of the threshold voltage of the eleventh transistor M11, that is, when V_{g}′−Vₛ′≤|Vₜₕ|′, the eleventh transistor M11 may be turned off. Therefore, the electrical connection between the second coupling capacitor C2 and the first node N1 may be disconnected, and the electrical connection between the second output terminal OUT2 and the first node N1 may be disconnected.

In the first cut-off level outputting stage t31, the second clock signal output terminal CK2 and the conduction level voltage terminal VGL may output the conduction levels, the input terminal IN of the shift register 10 may output the second cut-off level signal, and the first clock signal output terminal CK1, the third clock signal output terminal XCK and the first cut-off level voltage terminal VGH may output the cut-off levels. The third transistor M3 may be in conduction in response to the conduction level of the second clock signal output terminal CK2, and transmit the second cut-off level signal outputted by the input terminal IN of the shift register 10 to the third node N3; and the eighth transistor M8 may be in conduction in response to the conduction level of the conduction level voltage terminal VGL, and transmit the second cut-off level signal of the third node N3 to the fourth node N4. The ninth transistor M9 may be in conduction in response to the conduction level of the second clock signal output terminal CK2, and transmit the conduction level outputted by the conduction level voltage terminal VGL to the second node N2. The tenth transistor M10 may be turned off in response to the cut-off level of the third node N3. The sixth transistor M6 may be turned off in response to the second cut-off level signal of the fourth node N4. The seventh transistor M7 may be in conduction in response to the conduction level of the second node N2, and transmit the second cut-off level signal of the second cut-off level voltage terminal VGH2 to the second output terminal OUT2 of the shift register 10. The second output terminal OUT2 of the shift register 10 may output the second cut-off level signal. The eleventh transistor M11 may be in conduction in response to the conduction level of the conduction level voltage terminal VGL, and transmit the second cut-off level signal of the second output terminal OUT2 of the shift register 10 to the first node N1. The first transistor M1 may be turned off in response to the second cut-off level signal of the first node N1. The second transistor M2 may be in conduction in response to the conduction level of the second node N2, and transmit the first cut-off level signal of the first cut-off level voltage terminal VGH to the first output terminal OUT1 of the shift register 10. The first output terminal OUT1 of the shift register 10 may output the first cut-off level signal. The first storage capacitor C3 may store the conduction level of the second node N2.

Compared with the exiting technology, in various embodiments of the present application, the second cut-off level voltage signal with a higher voltage value may be outputted to the first node N1 and the fourth node N4 in the first cut-off level outputting stage t31, such that the gate turn-off voltages of the first transistor M1 and the sixth transistor M6 may be increased to turn off the first transistor M1 and the sixth transistor M6 more thoroughly. Therefore, the influence of the conduction level signal flowing in the first transistor M1 on the first cut-off level signal outputted by the shift register may be reduced, and the shift register may be ensured to output a stable first cut-off level signal; and the influence of the conduction level signal flowing in the sixth transistor M6 on the second cut-off level signal outputted by the shift register may be reduced, and the shift register may be ensured to output a stable second cut-off level signal.

In the second cut-off level outputting stage t32, the third clock signal output terminal XCK and the conduction level voltage terminal VGL may output the conduction levels, the second cut-off level voltage terminal VGH2 may output the second cut-off level signal, and the second clock signal output terminal CK2 and the first cut-off level voltage terminal VGH may output the cut-off levels. The fourth transistor M4 may be in conduction in response to the conduction level of the third clock signal output terminal XCK, the fifth transistor M5 may be in conduction in response to the conduction level of the second node N2, and the second cut-off level signal outputted by the second cut-off level voltage terminal VGH2 may be transmitted to the third node N3 via the fourth transistor M4 and the fifth transistor M5. The eighth transistor M8 may be in conduction in response to the conduction level of the conduction level voltage terminal VGL, and transmit the second cut-off level signal of the third node N3 to the fourth node N4. The first storage capacitor C3 may maintain the second node N2 at the conduction level. The sixth transistor M6 may be turned off in response to the second cut-off level signal of the fourth node N4. The seventh transistor M7 may be in conduction in response to the conduction level of the second node N2, and transmit the second cut-off level signal of the second cut-off level voltage terminal VGH2 to the second output terminal OUT2 of the shift register 10. The second output terminal OUT2 of the shift register 10 may output the second cut-off level signal. The eleventh transistor M11 may be in conduction in response to the conduction level of the conduction level voltage terminal VGL, and transmit the second cut-off level signal of the second output terminal OUT2 of the shift register 10 to the first node N1. The first transistor M1 may be turned off in response to the second cut-off level signal of the first node N1. The second transistor M2 may be in conduction in response to the conduction level of the second node N2, and the first cut-off level signal of the first cut-off level voltage terminal VGH may be transmitted to the first output terminal OUT1 of the shift register 10. The first output terminal OUT1 of the shift register 10 may output the first cut-off level signal.

Compared with the existing technology, in various embodiments of the present application, the second cut-off level voltage signal with a higher voltage value may be outputted to the first node N1 and the fourth node N4 in the second cut-off level outputting stage t32, such that the gate turn-off voltages of the first transistor M1 and the sixth transistor M6 may be increased to turn off the first transistor M1 and the sixth transistor M6 more thoroughly. Therefore, the influence of the conduction level signal flowing in the first transistor M1 on the first cut-off level signal outputted by the shift register may be reduced, and the shift register may be ensured to output a stable first off-level signal; and the influence of the conduction level signal flowing in the sixth transistor M6 on the second cut-off level signal outputted by the shift register may be reduced, and the shift register may be ensured to output a stable second cut-off level signal.

As shown in FIG. 19, in various embodiments of the present application, for the shift register at a current stage, the first clock signal output terminal CK1 may be reused as the third clock signal output terminal XCK. It should be understand that for the shift register at a previous stage or the shift register at a next stage, the first clock signal output terminal CK1 may be reused as the second clock signal output terminal CK2.

Based on the same technical concept as the shift register provided in the above-mentioned embodiments, correspondingly, the present application also provides an implementation manner of a driving method of the shift register. The shift register in the driving method may be the shift register 10 provided in the above-mentioned embodiments.

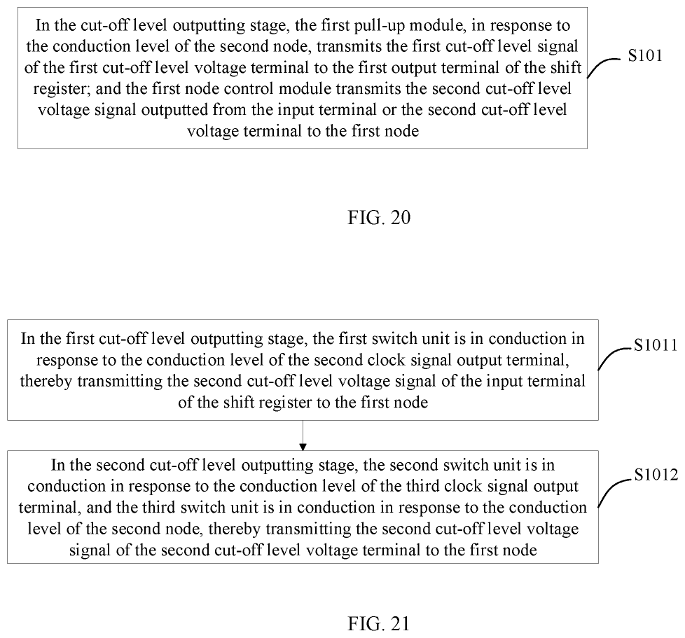

Referring to the following embodiments, as shown in FIG. 20, the driving method of the shift register provided by various embodiments of the present application may include S101: in the cut-off level outputting stage, the first pull-up module may, in response to the conduction level of the second node, transmit the first cut-off level signal of the first cut-off level voltage terminal to the first output terminal of the shift register; and the first node control module may transmit the second cut-off level voltage signal outputted from the input terminal or the second cut-off level voltage terminal to the first node, where the voltage value of the second cut-off level voltage signal may be greater than the voltage value of the first cut-off level signal.

In the driving method of the shift register of various embodiments of the present application, when the first output terminal of the shift register outputs the first cut-off level signal, the first node control module may transmit the second cut-off level voltage signal with a higher voltage value to the control terminal (first node) of the first pull-down module, such that the gate turn-off voltage of the first pull-down module may be increase to turn off the first pull-down module more thoroughly. Therefore, the influence of the conduction level signal flowing in the first pull-down module on the first cut-off level signal outputted by the shift register may be reduced, and the shift register may be ensured to output a stable first cut-off level signal.

As shown in FIG. 21, in some embodiments, the first node control module may transmit the second cut-off level voltage signal outputted from the input terminal or the second cut-off level voltage terminal to the first node, which may include S1011: in the first cut-off level outputting stage, the first switch unit may be in conduction in response to the conduction level of the second clock signal output terminal, thereby transmitting the second cut-off level voltage signal of the input terminal of the shift register to the first node; and also include S1012: in the second cut-off level outputting stage, the second switch unit may be in conduction in response to the conduction level of the third clock signal output terminal, and the third switch unit may be in conduction in response to the conduction level of the second node, thereby transmitting the second cut-off level voltage signal of the second cut-off level voltage terminal to the first node.

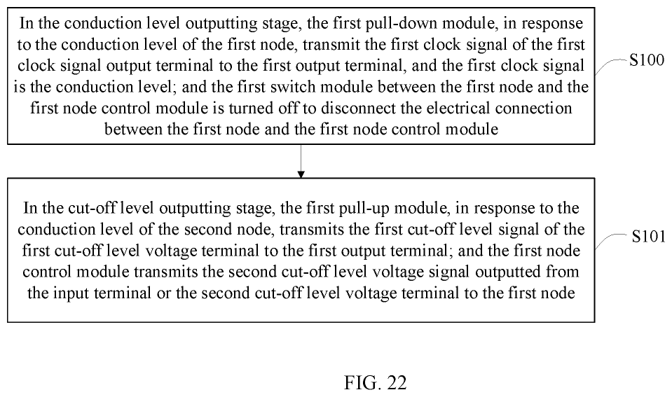

As shown in FIG. 22, in some embodiments, before the cut-off level outputting stage at S101, the driving method of the shift register may further include S100: in the conduction level outputting stage, the first pull-down module may, in response to the conduction level of the first node, transmit the first clock signal of the first clock signal output terminal to the first output terminal, and the first clock signal may be the conduction level; and the first switch module located between the first node and the first node control module may be turned off to disconnect the electrical connection between the first node and the first node control module.

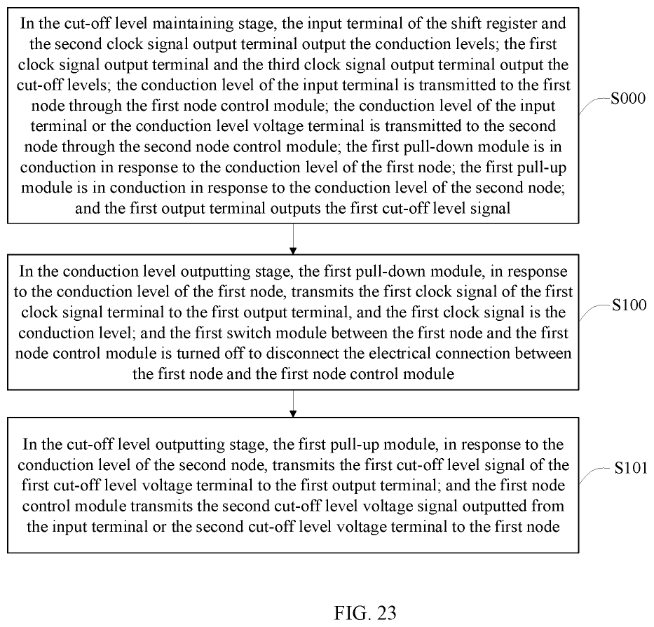

As shown in FIG. 23, in some embodiments, before the conduction level outputting stage at S100, the driving method of the shift register may further include S000: in the cut-off level maintaining stage, the input terminal of the shift register may and the second clock signal output terminal output the conduction levels; the first clock signal output terminal and the third clock signal output terminal may output the cut-off levels; the conduction level of the input terminal may be transmitted to the first node through the first node control module; the conduction level of the input terminal or the conduction level voltage terminal may be transmitted to the second node through the second node control module; the first pull-down module may be in conduction in response to the conduction level of the first node; the first pull-up module may be in conduction in response to the conduction level of the second node; and the first output terminal may output the first cut-off level signal.

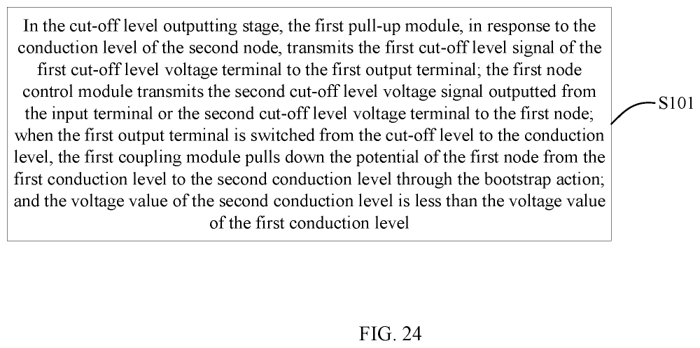

As shown in FIG. 24, in some embodiments, S101 may further include that, when the first output terminal is switched from the cut-off level to the conduction level, the first coupling module may pull down the potential of the first node from the first conduction level to the second conduction level through the bootstrap action; and the voltage value of the second conduction level may be less than the voltage value of the first conduction level.

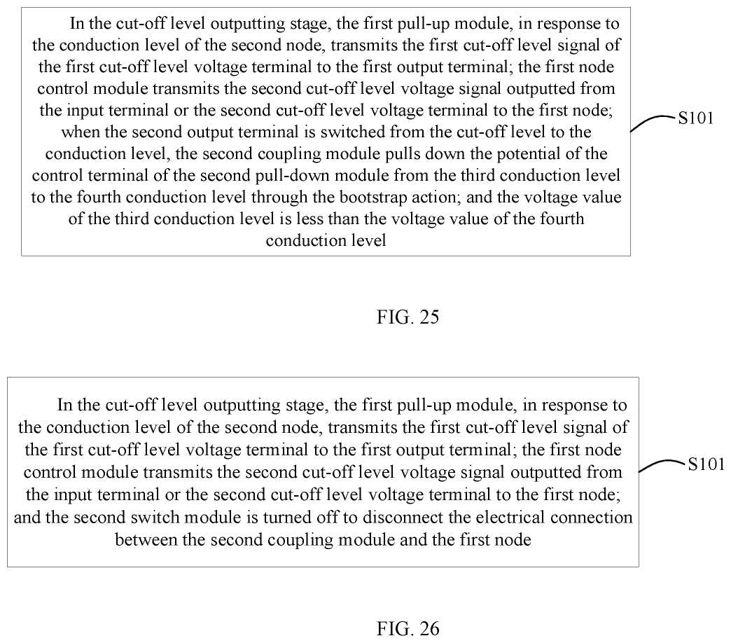

As shown in FIG. 25, in some embodiments, S101 may further include that, when the second output terminal is switched from the cut-off level to the conduction level, the second coupling module may pull down the potential of the control terminal of the second pull-down module from the third conduction level to the fourth conduction level through the bootstrap action; and the voltage value of the third conduction level is less than the voltage value of the fourth conduction level.

As shown in FIG. 26, in some embodiments, S101 may further include that the second switch module may be turned off to disconnect the electrical connection between the second coupling module and the first node.

The steps of the driving method of the shift register shown in FIGS. 20-26 have been described in detail in the above-mentioned description of the shift register. The driving method of the shift register in various embodiments of the present application may achieve same technical effect as that of the shift register. For concise description, the implementation process of each step may not be described in detail herein.

Based on the shift register provided by the above-mentioned embodiments, correspondingly, the present application also provides a gate electrode driving circuit which may include a plurality of cascaded shift registers provided by the above-mentioned embodiments.

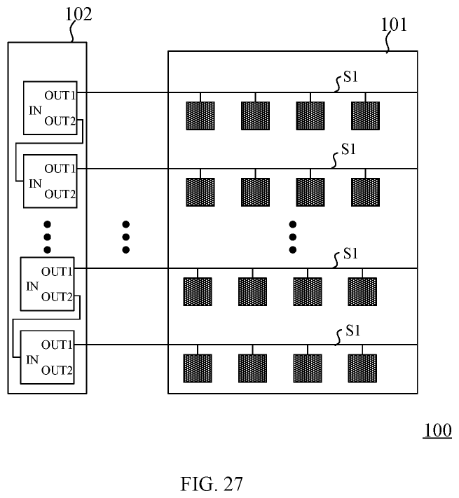

Based on the shift register provided in the above-mentioned embodiments, correspondingly, the present application also provides a display panel. As shown in FIG. 27, the display panel 100 may include a pixel array 101, where the pixel array 101 may include N gate lines Si sequentially arranged along a first direction, and N may be an integer greater than or equal to 2; and further include a gate electrode driving circuit 102, where the gate electrode driving circuit 102 may include N shift registers. Along the first direction, the first output terminals of the N shift registers may be connected to the N gate lines Si in a one-to-one correspondence; and the second output terminal of the n-th shift register in the N shift registers may be connected to the input terminal of the (n+1)-th shift register, where n∈[1, N].

The shift register in the gate driving circuit 102 may be the shift register 10 provided in the above-mentioned embodiments.

Correspondingly, the present application also provides a display device, which includes the display panel provided in various embodiments of the present application. In actual implementation, the display device may be any product or component with a display function, such as a mobile phone, a tablet computer, a TV, a monitor, a notebook computer, a digital photo frame, a navigator, and the like.

From the above-mentioned embodiments, it can be seen that the shift register and its driving method, and the display panel provided by the present disclosure may achieve at least the following beneficial effects.

For the shift register and the driving method, and the display panel in various embodiments of the present application, the shift register may include the first pull-down module, the first pull-up module, and the first node control module. When the first output terminal of the shift register outputs the first cut-off level signal, the first node control module may be configured to transmit the second cut-off level voltage signal with a higher voltage value to the control terminal (first node) of the first pull-down module, thereby increasing the gate turn-off voltage of the first pull-down module and more thoroughly turning off the first pull-down module. Therefore, the influence of the conduction level signal flowing in the first pull-down module on the first cut-off level signal outputted by the shift register may be reduced, and the shift register may be ensured to output a stable first cut-off level signal.

It should be noted that various embodiments in the present specification may be described in a progressive manner; same or similar parts between various embodiments may be referred to each other; and each embodiment may focus on the differences from other embodiments. Regarding the device embodiments, the corresponding part may refer to the description part of the method embodiments. Various embodiments of the present disclosure may not be limited to the steps and structures described above and shown in the drawings. Those skilled in the art may make various changes, modifications and additions, or change the order between steps after comprehending the spirit of various embodiments of the present disclosure. Furthermore, the detailed description of the existing technology may be omitted for brevity.

Various embodiments of the present disclosure may be implemented in other forms without departing from its spirit and essential characteristics. For example, the method or manner described in various embodiments may be modified, and the system architecture may not deviate from the basic spirit of various embodiments of the present disclosure. Therefore, various embodiments in the present disclosure may be regarded as illustrative rather than restrictive in all aspects, and the scope of various embodiments of the present disclosure may be defined by the appended claims rather than the above-mentioned description. Furthermore, all changes that fall within the meaning of the claims and the scope of equivalents may be thus included in the scope of various embodiments of the present disclosure.

What is claimed is:

1. A shift register, comprising:
a first pull-down module, wherein a control terminal of the first pull-down module is electrically connected to a first node, a first terminal of the first pull-down module is electrically connected to a first clock signal output terminal, and a second terminal of the first pull-down module is electrically connected to a first output terminal of the shift register, which are configured to, in response to a conduction level of the first node, transmit a first clock signal of the first clock signal output terminal to the first output terminal;
a first pull-up module, wherein a control terminal of the first pull-up module is electrically connected to a second node, a first terminal of the first pull-up module is electrically connected to a first cut-off level voltage terminal, and a second terminal of the first pull-up module is electrically connected to the first output terminal, which are configured to, in response to a conduction level of the second node, transmit a first cut-off level signal of the first cut-off level voltage terminal to the first output terminal; and
a first node control module, wherein the first node control module is electrically connected to each of the first node, an input terminal of the shift register and a second cut-off level voltage terminal, which is configured to, when the first cut-off level signal is outputted at the first output terminal, transmit a second cut-off level voltage signal outputted from one of the input terminal and the second cut-off level voltage terminal to the first node; and a voltage value of the second cut-off level voltage signal is greater than a voltage value of the first cut-off level signal.

2. The shift register according to claim 1, wherein:
the first node control module is further electrically connected to each of a second clock signal output terminal, a third clock signal output terminal and the second node, which is configured to, in response to a conduction level of the second clock signal output terminal, transmit the second cut-off level voltage signal of the input terminal to the first node, and configured to, in response to conduction levels of the third clock signal output terminal and the second node, transmit the second cut-off level voltage signal of the second cut-off level voltage terminal to the first node.

3. The shift register according to claim 1, further including:
a second pull-down module, wherein a control terminal of the second pull-down module is electrically connected to the first node, a first terminal of the second pull-down module is electrically connected to a third clock signal output terminal, and a second terminal of the second pull-down module is electrically connected to a second output terminal of the shift register, which are configured to, in response to the conduction level of the first node, transmit a third clock signal of the third clock signal output terminal to the second output terminal; and
a second pull-up module, wherein a control terminal of the second pull-up module is electrically connected to the second node, a first terminal of the second pull-up module is electrically connected to the second cut-off level voltage terminal, and a second terminal of the second pull-up module is electrically connected to the second output terminal, which are configured to, in response to the conduction level of the second node, transmit the second cut-off level voltage signal of the second cut-off level voltage terminal to the second output terminal,
wherein the first output terminal is electrically connected to a gate line of a pixel array, and the second output terminal is electrically connected to an input terminal of a shift register at a next stage.

4. The shift register according to claim 1, further including:
a first switch module, wherein a control terminal of the first switch module is electrically connected to a conduction level voltage terminal, a first terminal of the first switch module is electrically connected to the first node control module, and a second terminal of the first switch module is electrically connected to the first node, which are configured to disconnect an electrical connection between the first node and the first node control module in a conduction level outputting stage.

5. The shift register according to claim 1, further including:
a first coupling module, wherein a first terminal of the first coupling module is electrically connected to the first node, and a second terminal of the first coupling module is electrically connected to the first output terminal.

6. The shift register according to claim 4, further including:
a second node control module, wherein the second node control module is electrically connected to each of a third node, a second clock signal output terminal, the conduction level voltage terminal, the input terminal of the shift register and the second node, which is configured to, in response to a conduction level of the second clock signal output terminal, transmit conduction level voltage signals inputted from the input terminal and the conduction level voltage terminal to the second node, and configured to, in response to a conduction level of the third node, transmit the second cut-off level voltage signal inputted from the input terminal to the second node,
wherein the third node is between the first node control module and the first switch module.

7. The shift register according to claim 3, further including:
a second coupling module, wherein a first terminal of the second coupling module is electrically connected to the control terminal of the second pull-down module, and a second terminal of the second coupling module is electrically connected to the second terminal of the second pull-down module,
wherein the first node is electrically to the second output terminal of the shift register.

8. The shift register according to claim 7, further including:
a second switch module, wherein a control terminal of the second switch module is electrically connected to a conduction level voltage terminal, a first terminal of the second switch module is electrically connected to the second output terminal and the second terminal of the second coupling module respectively, and a second terminal of the second switch module is electrically connected to the first node, which are configured to, in a conduction level outputting stage, disconnect an electrical connection between the second coupling module and the first node.

9. The shift register according to claim 2, wherein:
the first clock signal output terminal is reused as the second clock signal output terminal, or the first clock signal output terminal is reused as the third clock signal output terminal.

10. The shift register according to claim 1, wherein:
the first pull-down module includes a first transistor, wherein a control terminal of the first transistor is electrically connected to the first node, a first terminal of the first transistor is electrically connected to the first clock signal output terminal, and a second terminal of the first transistor is electrically connected to the first output terminal;
the first pull-up module includes a second transistor, wherein a control terminal of the second transistor is electrically connected to the second node, a first terminal of the second transistor is electrically connected to the first cut-off level voltage terminal, and a second terminal of the second transistor is electrically connected to the first output terminal; and
the first node control module includes:
a first switch unit, wherein a control terminal of the first switch unit is electrically connected to a second clock signal output terminal, a first terminal of the first switch unit is electrically connected to the input terminal of the shift register, and a second terminal of the first switch unit is electrically connected to the first node;
a second switch unit, wherein a control terminal of the second switch unit is electrically connected to a third clock signal output terminal, and a first terminal of the second switch unit is electrically connected to the first node; and
a third switch unit, wherein a control terminal of the third switch unit is electrically connected to the second node, a first terminal of the third switch unit is electrically connected to the second cut-off level voltage terminal, and a second terminal of the third switch unit is electrically connected to a second terminal of the second switch unit.

11. The shift register according to claim 10, wherein:
the first switch unit includes at least two third transistors, wherein the at least two third transistors are arranged in series; control terminals of the at least two third transistors are each electrically connected to the second clock signal output terminal; a first terminal of one third transistor of the at least two third transistors is electrically connected to the input terminal; and a second terminal of another third transistor of the at least two third transistors is electrically connected to the first node;
the second switch unit includes a fourth transistor, wherein a control terminal of the fourth transistor is electrically connected to the third clock signal output terminal, and a first terminal of the fourth transistor is electrically connected to the first node; and
the third switch unit includes a fifth transistor, wherein a control terminal of the fifth transistor is electrically connected to the second node, a first terminal of the fifth transistor is electrically connected to the second cut-off level voltage terminal, and a second terminal of the fifth transistor is electrically connected to a second terminal of the fourth transistor.

12. The shift register according to claim 3, wherein:
the second pull-down module includes a sixth transistor, wherein a control terminal of the sixth transistor is electrically connected to the first node, a first terminal of the sixth transistor is electrically connected to the third clock signal output terminal, and a second terminal of the sixth transistor is electrically connected to the second output terminal; and
the second pull-up module includes a seventh transistor, wherein a control terminal of the seventh transistor is electrically connected to the second node, a first terminal of the seventh transistor is electrically connected to the second cut-off level voltage terminal, and a second terminal of the seventh transistor is electrically connected to the second output terminal.

13. The shift register according to claim 4, wherein:
the first switch module includes an eighth transistor, wherein a control terminal of the eighth transistor is electrically connected to the conduction level voltage terminal, a first terminal of the eighth transistor is electrically connected to the first node control module, and a second terminal of the eighth transistor is electrically connected to the first node.

14. The shift register according to claim 5, wherein:
the first coupling module includes a first coupling capacitor, wherein a first plate of the first coupling capacitor is electrically connected to the first node, and a second plate of the first coupling capacitor is electrically connected to the first output terminal.

15. The shift register according to claim 6, wherein:
the second node control module includes:
a ninth transistor, wherein a control terminal of the ninth transistor is electrically connected to the second clock signal output terminal, a first terminal of the ninth transistor is electrically connected to the conduction level voltage terminal, and a second terminal of the ninth transistor is electrically connected to the second node; and
a tenth transistor, wherein a control terminal of the tenth transistor is electrically connected to the third node, a first terminal of the tenth transistor is electrically connected to the input terminal of the shift register, and a second terminal of the tenth transistor is electrically connected to the second node.

16. The shift register according to claim 7, wherein:
the second coupling module includes a second coupling capacitor, wherein a first plate of the second coupling capacitor is electrically connected to the control terminal of the second pull-down module, and a second plate of the second coupling capacitor is electrically connected to the second terminal of the second pull-down module.

17. The shift register according to claim 16, wherein:
the second switch module includes an eleventh transistor, wherein a control terminal of the eleventh transistor is electrically connected to a conduction level voltage terminal; a first terminal of the eleventh transistor is electrically connected to the second output terminal and the second plate of the second coupling capacitor, respectively; and a second terminal of the eleventh transistor is electrically connected to the first node.

18. A driving method of a shift register, wherein the shift register includes a first pull-down module, a first pull-up module and a first node control module, wherein:
a control terminal of the first pull-down module is electrically connected to a first node, which is configured to, in response to a conduction level of the first node, transmit a first clock signal of a first clock signal output terminal to a first output terminal;
a control terminal of the first pull-up module is electrically connected to a second node, a first terminal of the first pull-up module is electrically connected to a first cut-off level voltage terminal, and a second terminal of the first pull-up module is electrically connected to the first output terminal of the shift register; and
the first node control module is electrically connected to each of the first node, an input terminal of the shift register and a second cut-off level voltage terminal; and
the driving method comprising:
in a cut-off level outputting stage, the first pull-up module, in response to a conduction level of the second node, transmitting a first cut-off level signal of the first cut-off level voltage terminal to the first output terminal; and the first node control module transmitting a second cut-off level voltage signal outputted from one of the input terminal and the second cut-off level voltage terminal to the first node,
wherein a voltage value of the second cut-off level voltage signal is greater than a voltage value of the first cut-off level signal.

19. The method according to claim 18, wherein:
the first node control module includes a first switch unit, a second switch unit and a third switch unit, wherein the first switch unit is configured between the input terminal and the first node; and the second switch unit and the third switch unit are each configured between the second cut-off level voltage terminal and the first node;
the cut-off level outputting stage includes a first cut-off level outputting stage and a second cut-off level outputting stage; and
the first node control module transmitting the second cut-off level voltage signal outputted from one of the input terminal and the second cut-off level voltage terminal to the first node includes:
in the first cut-off level outputting stage, the first switch unit being in conduction in response to a conduction level of a second clock signal output terminal, thereby transmitting the second cut-off level voltage signal of the input terminal of the shift register to the first node; and
in the second cut-off level outputting stage, the second switch unit being in conduction in response to a conduction level of a third clock signal output terminal, and the third switch unit being in conduction in response to the conduction level of the second node, thereby transmitting the second cut-off level voltage signal of the second cut-off level voltage terminal to the first node.

20. The method according to claim 18, before the cut-off level outputting stage, further including:
in a conduction level outputting stage, in response to the conduction level of the first node, transmitting the first clock signal of the first clock signal output terminal to the first output terminal by the first pull-down module, wherein the first clock signal is a conduction level; and
turning off a first switch module between the first node and the first node control module to disconnect an electrical connection between the first node and the first node control module.

21. The method according to claim 20, before the conduction level outputting stage, further including:
in a cut-off level maintaining stage, outputting conduction levels by the input terminal of the shift register and a second clock signal output terminal; outputting cut-off levels by the first clock signal output terminal and a third clock signal output terminal; transmitting the conduction level of the input terminal to the first node through the first node control module; transmitting the conduction level of the input terminal or a conduction level of a conduction level voltage terminal to the second node through a second node control module; the first pull-down module is in conduction in response to the conduction level of the first node; the first pull-up module being in conduction in response to the conduction level of the second node; and outputting the first cut-off level signal by the first output terminal.

22. The method according to claim 20, wherein:
the shift register further includes a first coupling module, connected between the first node and the first output terminal; and
the conduction level outputting stage further includes, when the first output terminal is switched from outputting a cut-off level to a conduction level, pulling down, by the first coupling module, a potential of the first node from a first conduction level to a second conduction level through a bootstrap action, wherein a voltage value of the second conduction level is less than a voltage value of the first conduction level.

23. The method according to claim 20, wherein:
the shift register further includes a second coupling module, wherein a first terminal of the second coupling module is electrically connected to a control terminal of a second pull-down module, a second terminal of the second coupling module is electrically connected to a second terminal of the second pull-down module and a second terminal of the shift register respectively; and
the conduction level outputting stage further includes, when the second output terminal is switched from outputting a cut-off level to a conduction level, pulling down, by the second coupling module, a potential of the control terminal of the second pull-down module from a third conduction level to a fourth conduction level through a bootstrap action, wherein a voltage value of the third conduction level is less than a voltage value of the fourth conduction level.

24. The method according to claim 23, wherein:
the shift register further includes a second switch module, wherein a control terminal of the second switch module is electrically connected to a conduction level voltage terminal; a first terminal of the second switch module is electrically connected to the second output terminal and the second terminal of the second coupling module respectively; and a second terminal of the second switch module is electrically connected to the first node; and
the conduction level outputting stage further includes, turning off the second switch module to disconnect an electrical connection between the second coupling module and the first node.

25. A display panel, comprising:
a pixel array, wherein the pixel array includes N gate lines sequentially arranged along a first direction, and N is an integer greater than or equal to 2;
a gate electrode driving circuit, wherein the gate electrode driving circuit includes N shift registers; along the first direction, first output terminals of N shift registers are connected to the N gate lines in a one-to-one correspondence; and a second output terminal of an n-th shift register in the N shift registers is connected to an input terminal of an (n+1)-th shift register, wherein n∈[1, N], and
a shift register of the N shift registers includes:
a first pull-down module, wherein a control terminal of the first pull-down module is electrically connected to a first node, a first terminal of the first pull-down module is electrically connected to a first clock signal output terminal, and a second terminal of the first pull-down module is electrically connected to a first output terminal of the shift register, which are configured to, in response to a conduction level of the first node, transmit a first clock signal of the first clock signal output terminal to the first output terminal;
a first pull-up module, wherein a control terminal of the first pull-up module is electrically connected to a second node, a first terminal of the first pull-up module is electrically connected to a first cut-off level voltage terminal, and a second terminal of the first pull-up module is electrically connected to the first output terminal, which are configured to, in response to a conduction level of the second node, transmit a first cut-off level signal of the first cut-off level voltage terminal to the first output terminal; and
a first node control module, wherein the first node control module is electrically connected to each of the first node, an input terminal of the shift register and a second cut-off level voltage terminal, which is configured to, when the first cut-off level signal is outputted at the first output terminal, transmit a second cut-off level voltage signal outputted from one of the input terminal and the second cut-off level voltage terminal to the first node; and a voltage value of the second cut-off level voltage signal is greater than a voltage value of the first cut-off level signal.
